(19) United States
(12) Patent Application Publication
(10) Pub. No.: US 2026/0313960 A1
(43) Pub. Date: Oct. 8, 2026

(54) SEMICONDUCTOR DEVICE INCLUDING CHANNEL LAYER

(71) Applicant: Samsung Electronics Co, Ltd., Suwon-si (KR)

(72) Inventors: Seungjin Jeong, Suwon-si (KR); Sungnam Lyu, Suwon-si (KR); Sanhyeok YU, Suwon-si (KR); Kyunghwan Lee, Suwon-si (KR); Dosun Lee, Suwon-si (KR); Sunjung Lee Lee, Suwon-si (KR); Eulji Jeong, Suwon-si (KR)

(73) Assignee: Samsung Electronics Co, Ltd., Suwon-si (KR)

(21) Appl. No.: 19/638,027

(22) Filed: Apr. 2, 2026

(30) Foreign Application Priority Data
Apr. 3, 2025 (KR) 10-2025-0043606

(51) Int. Cl. H10D 30/67; H10B 12/00; H10B 80/00; H10D 80/30; H10W 20/41; H10W 90/00

(52) U.S. Cl. CPC H10D 30/6728; H10B 12/315; H10B 12/482; H10B 12/485; H10B 12/488; H10B 12/50; H10D 30/6731; H10D 30/6757; H10W 20/435; H10B 12/05; H10B 12/33; H10B 80/00; H10D 80/30; H10W 90/792

(57) ABSTRACT

A semiconductor device includes a metal-containing conductive line, a metal-containing contact pattern apart from the metal-containing conductive line in a vertical direction and having a smaller length than the metal-containing conductive line, a channel layer extending in the vertical direction between the metal-containing conductive line and the metal-containing contact pattern and having an upper end contacting a first conductive member and a lower end spaced apart from a second conductive member, the first conductive member being one of the metal-containing conductive line and the metal-containing contact pattern, and the second conductive member being the other one thereof, and a silicon-containing metal nitride film between the second conductive member and the lower end of the channel layer and having a first surface contacting the second conductive member and a second surface contacting the channel layer.

### CROSS-REFERENCE TO RELATED APPLICATIONS

This present application claims priority to and the benefit under 35 U.S.C. § 119(a)-(d) of Korean Patent Application No. 10-2025-0043606, filed on Apr. 3, 2025, in the Korean Intellectual Property Office, the entire disclosure of which is incorporated herein by reference.

### FIELD

The disclosed concepts relate to a semiconductor device, and more particularly, to a semiconductor device including a channel layer including an oxide semiconductor.

### BACKGROUND

Due to the development of electronics technology, the downscaling of semiconductor devices has rapidly progressed. Accordingly, to reduce leakage current caused through a channel region, a transistor including a channel layer employing an oxide semiconductor material has been proposed.

### SUMMARY

According to aspects of the disclosed concepts, there is provided a semiconductor device including a metal-containing conductive line having a width in a first lateral direction and a length in a second lateral direction, wherein the second lateral direction is substantially perpendicular to the first lateral direction, a metal-containing contact pattern spaced apart from the metal-containing conductive line in a vertical direction, the metal-containing contact pattern having a smaller length than the metal-containing conductive line in the second lateral direction, a channel layer extending in the vertical direction between the metal-containing conductive line and the metal-containing contact pattern, the channel layer having an upper end in contact with a first conductive member and a lower end spaced apart from a second conductive member to face the second conductive member in the vertical direction, wherein the first conductive member is one of the metal-containing conductive line and the metal-containing contact pattern, and the second conductive member is the other one of the metal-containing conductive line and the metal-containing contact pattern, and a silicon-containing metal nitride film between the second conductive member and the lower end of the channel layer, the silicon-containing metal nitride film having a first surface in contact with a contact surface of the second conductive member and a second surface in contact with the lower end of the channel layer.

According to aspects of the disclosed concepts, there is provided a semiconductor device including a mold insulating pattern on a substrate, the mold insulating pattern defining a transistor region extending lengthwise in a first lateral direction, a channel layer located in the transistor region, the channel layer including a pair of vertical channel portions and a horizontal channel portion, the pair of vertical channel portions facing a sidewall of the mold insulating pattern in a second lateral direction and being spaced apart from one another in the second lateral direction, and the horizontal channel portion being located between the pair of vertical channel portions and integrally connected to one end of each of the pair of vertical channel portions, wherein the second lateral direction is substantially perpendicular to the first lateral direction, a first conductive member in contact with at least one of the pair of vertical channel portions of the channel layer, a second conductive member adjacent to the horizontal channel portion of the channel layer, the second conductive member being spaced apart from the first conductive member in the vertical direction with the channel layer therebetween, and a silicon-containing metal nitride film between the second conductive member and the channel layer, the silicon-containing metal nitride film having a first surface in contact with a contact surface of the second conductive member and a second surface in contact with the horizontal channel portion of the channel layer.

According to aspects of the disclosed concepts, there is provided a semiconductor device including a bit line having a width in a first lateral direction and a length in a second lateral direction, wherein the second lateral direction is substantially perpendicular to the first lateral direction, a pair of conductive contact patterns spaced apart from the bit line in a vertical direction and spaced apart from one another in the second lateral direction, each conductive contact pattern having a smaller length than the bit line in the second lateral direction, a mold insulating pattern between the bit line and the pair of conductive contact patterns in the vertical direction, the mold insulating pattern defining a transistor region extending lengthwise in the first lateral direction, a channel layer located in the transistor region, the channel layer including a pair of vertical channel portions and a horizontal channel portion, the pair of vertical channel portions facing a sidewall of the mold insulating pattern in the second lateral direction and being spaced apart from one another in the second lateral direction, and the horizontal channel portion being located between the pair of vertical channel portions and integrally connected to one end of each of the pair of vertical channel portions, a pair of word lines located in the transistor region, the pair of word lines respectively facing and corresponding to the pair of vertical channel portions of the channel layer, and a silicon-containing metal nitride film in contact with a bottom surface of the horizontal channel portion of the channel layer, wherein the bit line and one of the pair of conductive contact patterns are in contact with the pair of vertical channel portions of the channel layer, and the bit line and the other one of the pair of conductive contact patterns are adjacent to the horizontal channel portion of the channel layer, have contact surfaces in contact with the silicon-containing metal nitride film, and are spaced apart from the horizontal channel portion of the channel layer with the silicon-containing metal nitride film therebetween.

### BRIEF DESCRIPTION OF THE DRAWINGS

Embodiments will be more clearly understood from the following detailed description taken in conjunction with the accompanying drawings in which:

FIG. 1 is a plan layout diagram of some components of a semiconductor device according to embodiments;

FIG. 2 is a cross-sectional view taken along line A-A′ of FIG. 1;

FIG. 3 is a cross-sectional view taken along line B-B′ of FIG. 1;

FIG. 4 is an enlarged cross-sectional view of a portion “EX1” in FIG. 2;

FIGS. 5A and 5B are each a graph for explaining an example of a content ratio of silicon atoms in a silicon-containing metal nitride film included in a semiconductor device according to embodiments;

FIG. 6 is a cross-sectional view of a semiconductor device according to embodiments;

FIG. 7 is a cross-sectional view of a semiconductor device according to embodiments;

FIG. 8 is an enlarged cross-sectional view of a portion “EX3” in FIG. 7;

FIGS. 9A and 9B are each a graph for explaining an example of a content ratio of silicon atoms in a silicon-containing metal nitride film included in a semiconductor device according to embodiments;

FIG. 10 is a cross-sectional view of a semiconductor device according to embodiments;

FIG. 11 is a cross-sectional view of a semiconductor device according to embodiments;

FIGS. 12A to 20 are diagrams of a process sequence of a method of manufacturing a semiconductor device, according to embodiments, wherein FIGS. 12A, 13A, and 18A are plan layout diagrams of some components, according to the process sequence, which illustrate a method of manufacturing a semiconductor device, FIGS. 12B, 13B, 14A, 15A, 16, 17, 18B, 19, and 20 are cross-sectional views of a portion corresponding to line A-A′ of FIG. 1, according to the process sequence, and FIGS. 14B and 15B are cross-sectional views of a portion corresponding to line B-B′ of FIG. 1, according to the process sequence; and

FIGS. 21A, 21B, and 21C are cross-sectional views of a process sequence of a method of manufacturing a semiconductor device, according to embodiments.

### DETAILED DESCRIPTION

Hereinafter, embodiments will be described in detail with reference to the accompanying drawings. The same reference numerals are used to denote the same elements in the drawings, and repeated descriptions thereof will be omitted.

The disclosed concepts provide a semiconductor device having a structure with improved electrical properties and reliability while ensuring electrical connection between a channel layer and a conductive line or a conductive pattern connected to the channel layer in a transistor including the channel layer that employs an oxide semiconductor material.

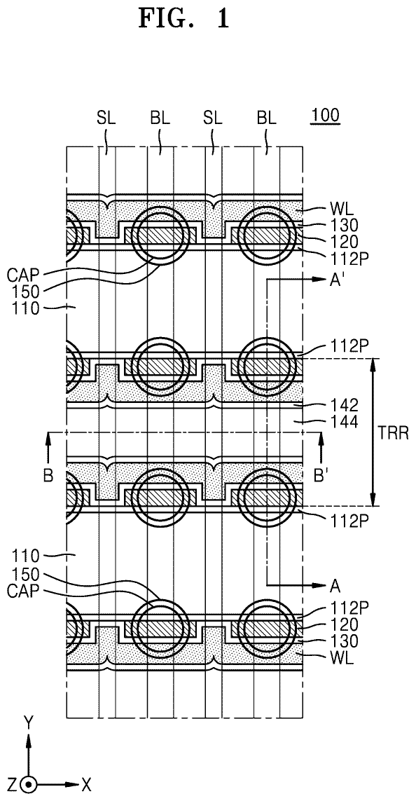

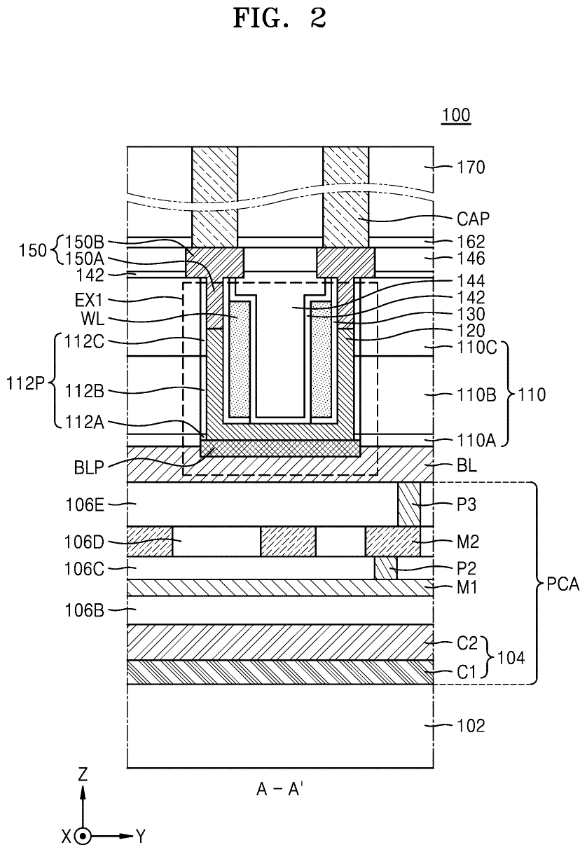

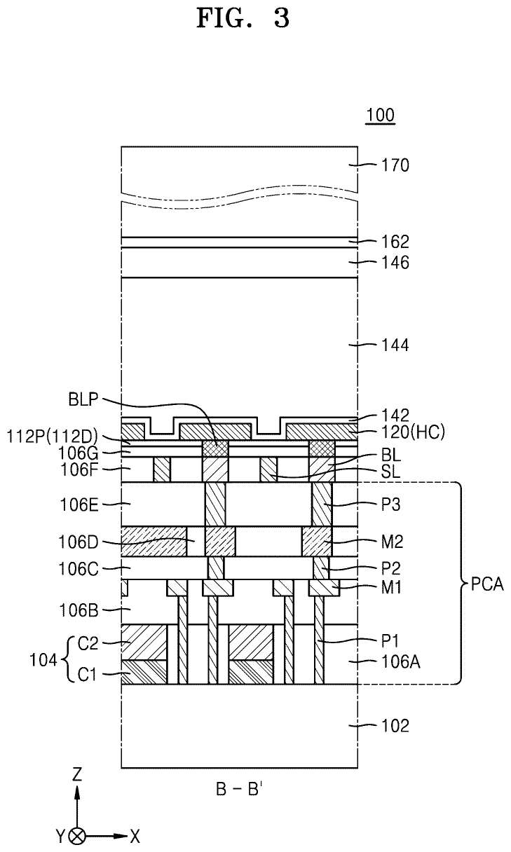

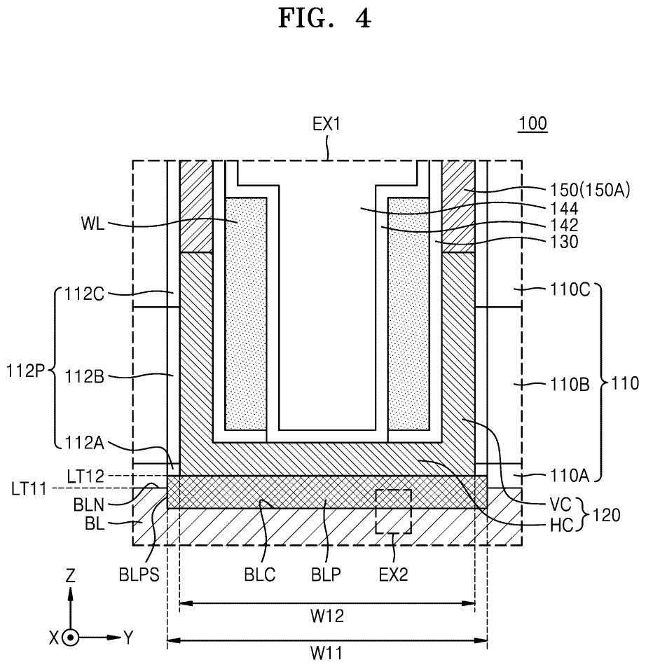

FIG. 1 is a plan layout diagram of some components of a semiconductor device 100 according to embodiments. FIG. 2 is a cross-sectional view taken along line A-A′ of FIG. 1. FIG. 3 is a cross-sectional view taken along line B-B′ of FIG. 1. FIG. 4 is an enlarged cross-sectional view of a portion “EX1” in FIG. 2.

Referring to FIGS. 1 to 4, the semiconductor device 100 may include a substrate 102, a peripheral circuit structure PCA arranged on the substrate 102, and a plurality of bit lines BL and a plurality of shield structures SL arranged on the peripheral circuit structure PCA. The peripheral circuit structure PCA may include a plurality of peripheral circuits.

In embodiments, the substrate 102 may include silicon, for example, single crystalline silicon, polycrystalline silicon, or amorphous silicon. In other embodiments, the substrate 102 may include at least one selected from germanium (Ge), silicon germanium (SiGe), silicon carbide (SiC), gallium arsenide (GaAs), indium arsenide (InAs), and indium phosphide (InP). In embodiments, the substrate 102 may include a conductive region, for example, a doped well or a doped structure.

Each of the plurality of bit lines BL may be connected to at least one of the plurality of peripheral circuits included in the peripheral circuit structure PCA. Each of the plurality of shield structures SL may be floated. The plurality of bit lines BL and the plurality of shield structures SL may be insulated from one another by an interlayer insulating film 106F. The plurality of shield structures SL may be covered by an interlayer insulating film 106G. The plurality of bit lines BL may be connected to the peripheral circuit included in the peripheral circuit structure PCA through a plurality of conductive plugs (e.g., P1, P2, and P3) included in the peripheral circuit structure PCA and some selected ones of a plurality of wiring layers (e.g., M1 and M2).

The peripheral circuit structure PCA may include a plurality of core circuits 104. The plurality of core circuits 104 may include a first conductive pattern C1 and a second conductive pattern C2, which are sequentially arranged on the substrate 102. The first conductive pattern C1 and the second conductive pattern C2 may constitute various circuit elements, which are located in the peripheral circuit structure PCA and configured to control functions of unit elements arranged on the upper portion of the peripheral circuit structure (PCA). In embodiments, the peripheral circuit structure PCA may further include various active elements (e.g. transistors) and various passive elements (e.g., capacitors, resistors, and inductors).

In embodiments, a plurality of peripheral circuits included in the peripheral circuit structure PCA may include a sub-word line driver block (SWD), a sense amplifier block (S/A), and/or a control logic, without being limited thereto. The plurality of peripheral circuits included in the peripheral circuit structure PCA may include an NMOS transistor and a PMOS transistor. The plurality of peripheral circuits may be electrically connected to conductive lines (e.g., the plurality of bit lines BL) located on the peripheral circuit structure PCA through the plurality of conductive plugs (e.g., P1, P2, and P3), and the plurality of wiring layers (e.g., M1 and M2).

In the peripheral circuit structure PCA, from among the plurality of core circuits 104, the plurality of conductive plugs (e.g., P1, P2, and P3), and the plurality of wiring layers (e.g., M1 and M2), portions that need to be insulated from one another may be maintained a required insulation distance apart from one another by a plurality of interlayer insulating films (e.g., 106A, 106B, 106C, 106D, and 106E). The plurality of interlayer insulating films (e.g., 106A, 106B, 106C, 106D, and 106E) may each include an oxide film, a nitride film, or a combination thereof, without being limited thereto.

In embodiments, the peripheral circuit structure PCA on the substrate 102 may be omitted. In this case, the peripheral circuit structure PCA may be located in another region spaced apart from a region shown in FIGS. 2 and 3 on the substrate 102. In embodiments, the peripheral circuit structure PCA may be located in a region spaced apart from a cell array region including a transistor region (refer to TRR in FIG. 1) in a lateral direction.

The plurality of bit lines BL and the plurality of shield structures SL may be spaced apart from one another in a first lateral direction (X direction) on the substrate 102 and extend lengthwise in a second lateral direction (Y direction), which is perpendicular to the first lateral direction (X direction). Each of the plurality of bit lines BL may have a width in the first lateral direction (X direction) and have a length in the second lateral direction (Y direction). Each of the plurality of bit lines BL may have the length in the second lateral direction (Y direction), which is greater than the width in the first lateral direction (X direction).

The plurality of bit lines BL and the plurality of shield structures SL may extend parallel to one another in the second lateral direction (Y direction). In embodiments, the plurality of bit lines BL may each include a metal-containing film. In embodiments, the plurality of bit lines BL may each include titanium (Ti), titanium nitride (TiN), tantalum (Ta), tantalum nitride (TaN), molybdenum (Mo), ruthenium (Ru), tungsten (W), tungsten nitride (WN), cobalt (Co), nickel (Ni), titanium silicide (TiSi), titanium silicon nitride (TiSiN), tungsten silicide (WSi), tungsten silicon nitride (WSiN), tantalum silicide (TaSi), tantalum silicon nitride (TaSiN), ruthenium titanium nitride (RuTiN), cobalt silicide (CoSi), nickel silicide (NiSi), or a combination thereof. In embodiments, the plurality of bit lines BL may each include a conductive metal nitride film. For example, the plurality of bit lines BL may include TiN, without being limited thereto. As used herein, the bit line BL may be referred to as a metal-containing conductive line or a second conductive member. In embodiments, the plurality of shield structures SL may each include tungsten (W), aluminum (Al), copper (Cu), or a combination thereof, without being limited thereto. In embodiments, the plurality of shield structures SL may each include a conductive film including W, Al, Cu, or a combination thereof and air gaps or voids formed inside the conductive film.

A mold insulating pattern 110 may be arranged on the plurality of bit lines BL and the plurality of shield structures SL. The mold insulating pattern 110 may have a sidewall defining the transistor region (refer to TRR in FIG. 1). The mold insulating pattern 110 and the transistor region TRR defined by the sidewall of the mold insulating pattern 110 may each extend lengthwise in the first lateral direction (X direction). The mold insulating pattern 110 may include a first mold insulating pattern 110A, a second mold insulating pattern 110B, and a third mold insulating pattern 110C, which are sequentially stacked on the plurality of bit lines BL and the interlayer insulating film 106G in a vertical direction (Z direction). The first mold insulating pattern 110A, the second mold insulating pattern 110B, and the third mold insulating pattern 110C may each include a silicon oxide film, a silicon nitride film, or a combination thereof. For example, the first mold insulating pattern 110A and the third mold insulating pattern 110C may each include a silicon nitride film, and the second mold insulating pattern 110B may include a silicon oxide film. In embodiments, the third mold insulating pattern 110C may be omitted in the mold insulating pattern 110. In this case, the mold insulating pattern 110 may include the first mold insulating pattern 110A and the second mold insulating pattern 110B, the first mold insulating pattern 110A may include a silicon nitride film, and the second mold insulating pattern 110B may include a silicon oxide film.

As shown in FIGS. 1 and 2, in the transistor region TRR, a plurality of channel layers 120 may be arranged in a line in the first lateral direction (X direction). Each of the plurality of channel layers 120 may include a horizontal channel portion HC and a pair of vertical channel portions VC. The horizontal channel portion HC may be adjacent to the bit line BL and extend lengthwise in the second lateral direction (Y direction). The pair of vertical channel portions VC may extend in the vertical direction (Z direction) from both ends in the second lateral direction (Y direction) of the horizontal channel portion HC. The pair of vertical channel portions VC included in one channel layer 120 may be spaced apart from one another with the horizontal channel portion HC therebetween in the second lateral direction (Y direction). The horizontal channel portion HC may be integrally connected to one end of each of the pair of vertical channel portions VC. In each of the plurality of channel layers 120, the pair of vertical channel portions VC may face the sidewall of the mold insulating pattern 110.

A plurality of transistors including the plurality of channel layers 120 may be arranged in the transistor region TRR. The plurality of transistors may include two transistors facing one another in the second lateral direction (Y direction), and the two transistors may share a selected one of the plurality of channel layers 120 therebetween.

The channel layer 120 may include an oxide semiconductor layer. In embodiments, the channel layer 120 may include indium gallium zinc oxide (InGaZnO or IGZO), tin (Sn)-IGZO, indium tungsten oxide (InWO or IWO), indium zinc oxide (InZnO or IZO), zinc tin oxide (ZnSnO or ZTO), zinc oxide (ZnO), yttrium-doped zinc oxide (YZO), indium gallium silicon oxide (InGaSiO or IGSO), indium oxide (InO), tin oxide (SnO), titanium oxide (TiO), zinc oxynitride (ZnON), magnesium zinc oxide (MgZnO), zirconium indium zinc oxide (ZrInZnO), hafnium indium zinc oxide (HfInZnO), tin indium zinc oxide (SnInZnO), silicon indium zinc oxide (SiInZnO), gallium zinc tin oxide (GaZnSnO), zirconium zinc tin oxide (ZrZnSnO), or a combination thereof. For example, the channel layer 120 may include IGZO.

A silicon-containing metal nitride film BLP may be between the bit line BL and the horizontal channel portion HC of the channel layer 120. The silicon-containing metal nitride film BLP may have a surface (referred to as a first surface) in contact with a contact surface BLC of the bit line BL, which is adjacent to the channel layer 120, and a surface (referred to as a second surface) in contact with the horizontal channel portion HC of the channel layer 120.

The silicon-containing metal nitride film BLP may have a tunneling-permissive thickness to enable electrical connection between the bit line BL and the channel layer 120. For example, the silicon-containing metal nitride film BLP may have a thickness of about 10 Å to about 50 Å in the vertical direction (Z direction), without being limited thereto.

When the bit line BL includes a TiN film, the silicon-containing metal nitride film BLP may include a TiSiN film. An atomic ratio of Si/(Ti+Si) in the TiSiN film included in the silicon-containing metal nitride film BLP may be within a range of about 0.2 to about 1.0.

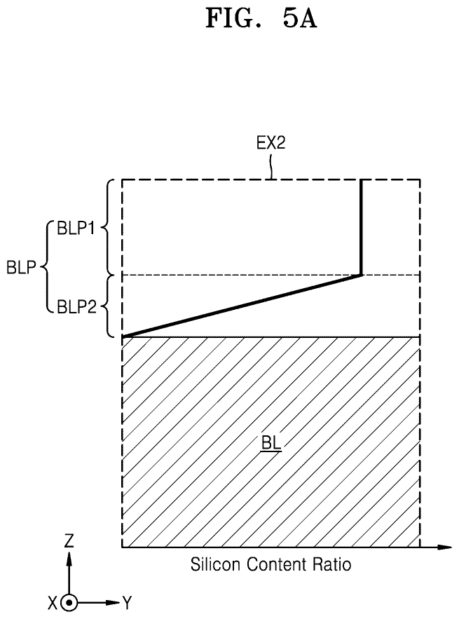

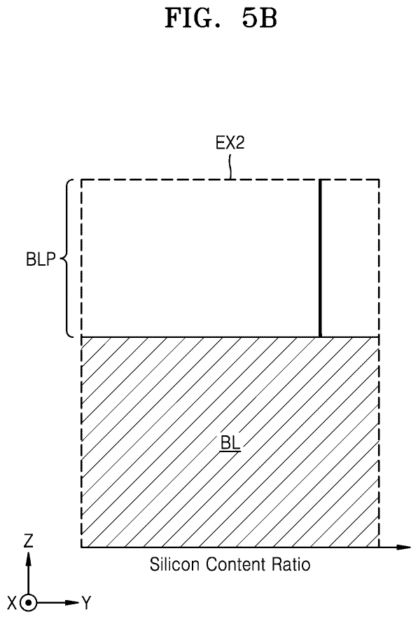

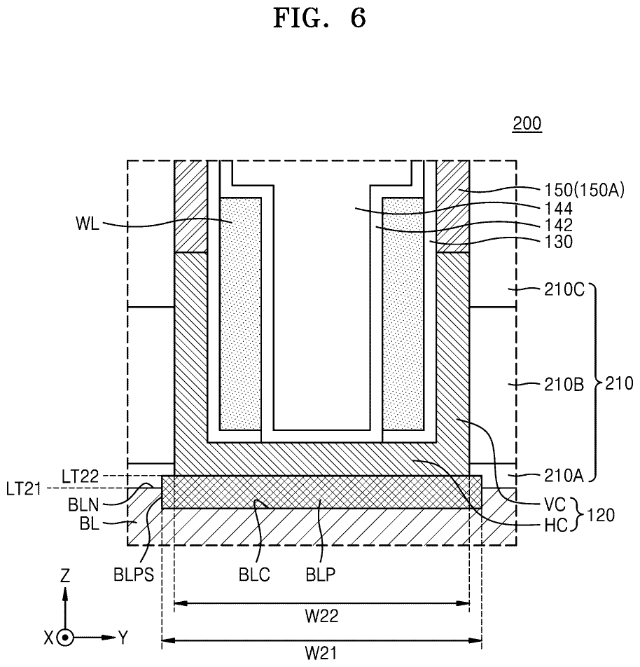

FIGS. 5A and 5B are each a graph for explaining an example of a content ratio of silicon atoms in the silicon-containing metal nitride film BLP. FIGS. 5A and 5B each illustrate a variation in the content ratio of silicon atoms in a partial region of the silicon-containing metal nitride film BLP, of region “EX2” of FIG. 4.

In embodiments, as shown in FIG. 5A, a content ratio of silicon (Si) atoms in the silicon-containing metal nitride film BLP may be variable in the vertical direction (Z direction). The silicon-containing metal nitride film BLP may include a first portion BLP1 in which a content ratio of silicon (Si) atoms in the silicon-containing metal nitride film BLP is constant regardless of a distance from the bit line BL in the vertical direction (Z direction) and a second portion BLP2 in which a content ratio of silicon (Si) atoms in the silicon-containing metal nitride film BLP gradually increases in a direction far away from the bit line BL in the vertical direction (Z direction). In the silicon-containing metal nitride film BLP, the second portion BLP2 may be in contact with the bit line BL, and the first portion BLP1 may be spaced apart from the bit line BL with the second portion BLP2 therebetween in the vertical direction (Z direction).

In embodiments, as shown in FIG. 5B, a content ratio of silicon (Si) atoms in the silicon-containing metal nitride film BLP may be constant in the vertical direction (Z direction). That is, a content ratio of silicon (Si) atoms in the silicon-containing metal nitride film BLP may be constant regardless of the distance from the bit line BL in the vertical direction (Z direction).

The peripheral circuit structure PCA shown in FIGS. 2 and 3 may be spaced apart from the channel layer 120 with the bit line BL and the silicon-containing metal nitride film BLP therebetween in the vertical direction (Z direction). The bit line BL may include a non-contact surface BLN in contact with the mold insulating pattern 110. A first thickness from the contact surface BLC of the bit line BL to a bottom surface of the bit line BL in the vertical direction (Z direction) may be less than a second thickness from the non-contact surface BLN of the bit line BL to the bottom surface of the bit line BL in the vertical direction (Z direction). As used herein, the bottom surface of the bit line BL refers to a surface facing the substrate 102, from among surfaces of the bit line BL.

A vertical level LT11 of the non-contact surface BLN of the bit line BL may be closer to the substrate 102 than a vertical level LT12 of a surface of the silicon-containing metal nitride film BLP, which is in contact with the horizontal channel portion HC of the channel layer 120. In the present embodiment, a vertical level refers to a distance from the substrate 102 in the vertical direction (Z direction).

In the second lateral direction (Y direction), a width W11 of the silicon-containing metal nitride film BLP may be greater than a width W12 of the horizontal channel portion HC of the channel layer 120 and less than a width of the bit line BL. In the second lateral direction (Y direction), both sidewalls BLPS of the silicon-containing metal nitride film BLP may protrude toward the mold insulating pattern 110 in the second lateral direction (Y direction) further than an outer surface of the vertical channel portion VC of the channel layer 120, which faces the mold insulating pattern 110.

As shown in FIGS. 2 and 4, an insulating liner structure 112P may be between the mold insulating pattern 110 and the vertical channel portion VC of the channel layer 120 in the second lateral direction (Y direction). The insulating liner structure 112P may have a surface (referred to as a first surface) in contact with the mold insulating pattern 110 and a surface (referred to as a second surface) in contact with the vertical channel portion VC of the channel layer 120.

The insulating liner structure 112P may include a portion overlapping the silicon-containing metal nitride film BLP in the vertical direction (Z direction). As shown in FIGS. 2 and 4, the insulating liner structure 112P may include a first insulating liner portion 112A, a second insulating liner portion 112B, and a third insulating liner portion 112C, which are sequentially arranged on a top surface of the silicon-containing metal nitride film BLP in the vertical direction (Z direction).

In the insulating liner structure 112P, the first insulating liner portion 112A may be in contact with the first mold insulating pattern 110A of the mold insulating pattern 110, the second insulating liner portion 112B may be in contact with the second mold insulating pattern 110B of the mold insulating pattern 110, and the third insulating liner portion 112C may be in contact with the third mold insulating pattern 110C of the mold insulating pattern 110. When, in the mold insulating pattern 110, each of the first mold insulating pattern 110A and the third mold insulating pattern 110C includes a silicon nitride film and the second mold insulating pattern 110B includes a silicon oxide film, in the insulating liner structure 112P, each of the first insulating liner portion 112A and the third insulating liner portion 112C may include a silicon nitride film, and the second insulating liner portion 112B may include a silicon oxide film. Here, a content ratio of nitrogen atoms in the silicon nitride film included in each of the first mold insulating pattern 110A and the third mold insulating pattern 110C may be higher than a content ratio of nitrogen atoms in the silicon nitride film included in each of the first insulating liner portion 112A and the third insulating liner portion 112C. In addition, a content ratio of oxygen atoms in the silicon oxide film included in the second mold insulating pattern 110B may be higher than a content ratio of oxygen atoms in the silicon oxide film included in the second insulating liner portion 112B.

As shown in FIG. 3, the insulating liner structure 112P may further include a fourth insulating liner portion 112D between two adjacent ones of a plurality of silicon-containing metal nitride films BLP. The fourth insulating liner portion 112D may have a top surface in contact with a bottom surface of the horizontal channel portion HC of the channel layer 120. A bottom surface of the fourth insulating liner portion 112D may be in contact with a top surface of the interlayer insulating film 106G. When the interlayer insulating film 106G includes a silicon oxide film, the fourth insulating liner portion 112D may include a silicon oxide film. Here, a content ratio of oxygen atoms in the silicon oxide film included in the interlayer insulating film 106G may be higher than a content ratio of oxygen atoms in the silicon oxide film included in the fourth insulating liner portion 112D. When the interlayer insulating film 106G includes a silicon nitride film, the fourth insulating liner portion 112D may include a silicon nitride film. Here, a content ratio of nitrogen atoms in the silicon nitride film included in the interlayer insulating film 106G may be higher than a content ratio of nitrogen atoms in the silicon nitride film included in the fourth insulating liner portion 112D.

As shown in FIGS. 1 and 2, a gate dielectric film 130 covering the channel layer 120 and a plurality of word lines WL covering the gate dielectric film 130 may be arranged in the transistor region TRR. The plurality of word lines WL may extend lengthwise in the first lateral direction (X direction) and be arranged parallel to one another. One word line WL may be in contact with one gate dielectric film 130 in the transistor region TRR. Each of the plurality of channel layers 120 may be opposite to the word line WL with the gate dielectric film 130 therebetween in the second lateral direction (Y direction).

In the transistor region TRR, the word line WL may be located on one side of the vertical channel portion VC of the channel layer 120 in the second lateral direction (Y direction), and the gate dielectric film 130 may be between the vertical channel portion VC of the channel layer 120 and the word line WL. In the transistor region TRR, a pair of word lines WL, which are adjacent to one another in the second lateral direction (Y direction), may respectively face and correspond to the pair of vertical channel portions VC included in the channel layer 120 adjacent thereto. The mold insulating pattern 110 may be arranged on another side of the vertical channel portion VC of the channel layer 120 in the second lateral direction (Y direction). The mold insulating pattern 110 may be spaced apart from the gate dielectric film 130 with the vertical channel portion VC of the channel layer 120 therebetween in the second lateral direction (Y direction).

As shown in FIG. 1, each of the plurality of word lines WL may include a portion located opposite to the channel layer 120 with the gate dielectric film 130 therebetween and a portion located opposite to the mold insulating pattern 110 with the gate dielectric film 130 therebetween. As shown in FIG. 2, the bit line BL may be spaced apart from the word line WL in the vertical direction (Z direction) with the silicon-containing metal nitride film BLP, the channel layer 120, and the gate dielectric film 130 therebetween.

One channel layer 120 may face one surface of each of two word lines WL. The gate dielectric film 130 may be between the channel layer 120 and the word line WL. The gate dielectric film 130 may include a portion between the word line WL and the vertical channel portion VC of the channel layer 120 and a portion between the word line WL and the horizontal channel portion HC of the channel layer 120.

In embodiments, the gate dielectric film 130 may include a high-k dielectric film having a higher dielectric constant than a silicon oxide film. In embodiments, the gate dielectric film 130 may include at least one material selected from hafnium oxide (HfO), hafnium silicate (HfSiO), hafnium oxynitride (HfON), hafnium silicon oxynitride (HfSiON), lathanum oxide (LaO), lathanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (SrBiTaO), bismuth iron oxide (BFO), strontium titanium oxide (SrTiO), yttrium oxide (YO), aluminum oxide (AlO), and lead scandium tantalum oxide (PbScTaO). The plurality of word lines WL may each include Ti, TiN, Ta, TaN, Mo, Ru, W, WN, TiSiN, WSiN, polysilicon, or a combination thereof.

In the transistor region TRR, a lower insulating liner 142 and an upper insulating barrier wall 144 may be arranged on the channel layer 120 between two word lines WL that are spaced apart from one another in the second lateral direction (Y direction). The lower insulating liner 142 and the upper insulating barrier wall 144 may include insulating films including different materials. For example, the lower insulating liner 142 may include a silicon nitride film, and the upper insulating barrier wall 144 may include a silicon oxide film, without being limited thereto.

A plurality of conductive contact patterns 150 may be arranged on the plurality of channel layers 120. Each of the plurality of conductive contact patterns 150 may be connected to a selected one of the plurality of channel layers 120. As used herein, the conductive contact pattern 150 may be referred to as a metal-containing contact pattern or a first conductive member. Each of the plurality of conductive contact patterns 150 may be spaced apart from the bit line BL with the channel layer 120 therebetween in the vertical direction (Z direction) Each of the plurality of conductive contact patterns 150 may have a length less than a length of the bit line BL in the second lateral direction (Y direction). A portion of the lower insulating liner 142 and a portion of an upper insulating film 146 may be between two adjacent ones of the plurality of conductive contact patterns 150. The upper insulating film 146 may include a silicon nitride film, without being limited thereto.

The vertical channel portion VC of each of the plurality of channel layers 120 may extend in the vertical direction (Z direction) between the bit line BL and the conductive contact pattern 150. The vertical channel portion VC of each of the plurality of channel layers 120 may have an upper end, which is in contact with a selected one of the plurality of conductive contact patterns 150. Each of the plurality of conductive contact patterns 150 may be in contact with a selected one of the pair of vertical channel portions VC included in one channel layer 120. The horizontal channel portion HC of each of the plurality of channel layers 120 may have a lower end, which is spaced apart from the bit line BL in the vertical direction (Z direction) and faces the bit line BL in the vertical direction (Z direction).

Each of the plurality of conductive contact patterns 150 may include a bottom surface in contact with a top surface of the vertical channel portion VC of the channel layer 120, a first sidewall facing the word line WL in the second lateral direction (Y direction), and a second sidewall facing the mold insulating pattern 110 in the second lateral direction (Y direction). The first sidewall and the second sidewall of each of the plurality of conductive contact patterns 150 may be sidewalls that are opposite to one another in the second lateral direction (Y direction). In each of the plurality of conductive contact patterns 150, the second sidewall facing the mold insulating pattern 110 may be in contact with the insulating liner structure 112P.

Each of the plurality of conductive contact patterns 150 may include a metal-containing film. In embodiments, the plurality of conductive contact patterns 150 may each include Ti, TiN, Ta, TaN, Mo, Ru, W, WN, TiSiN, WSiN, or a combination thereof. In embodiments, each of the plurality of conductive contact patterns 150 may include a conductive metal nitride film. For example, the plurality of conductive contact patterns 150 may each include TiN.

As shown in FIG. 1, the plurality of conductive contact patterns 150 may be regularly arranged a predetermined distance apart from one another in the first lateral direction (X direction) and the second lateral direction (Y direction). FIG. 1 illustrates an example in which the plurality of conductive contact patterns 150 are arranged to have a matrix structure in a plan view (e.g., on an X-Y plane) on the substrate 102, but the disclosed concepts are not limited thereto. For example, the plurality of conductive contact patterns 150 may be arranged to have a honeycomb structure in the plan view (e.g., on the X-Y plane) on the substrate 102.

As shown in FIG. 2, each of the plurality of conductive contact patterns 150 may include a lower contact portion 150A and an upper contact portion 150B. The lower contact portion 150A may be between the mold insulating pattern 110 and the gate dielectric film 130 and be in contact with the top surface of the vertical channel portion VC of the channel layer 120, and the upper contact portion 150B may be located on a top surface of the mold insulating pattern 110 and integrally connected to the lower contact portion 150A. In the second lateral direction (Y direction), a width of the upper contact portion 150B may be greater than a width of the lower contact portion 150A. The upper contact portion 150B of each of the plurality of conductive contact patterns 150 may serve as a landing pad on which the capacitor structure CAP located thereon lands.

The plurality of conductive contact patterns 150 may include a conductive contact pattern 150 (referred to as a first conductive contact pattern) in contact with one of the pair of vertical channel portions VC included in one channel layer 120 and a conductive contact pattern 150) (referred to as a second conductive contact pattern) in contact with the other one of the pair of vertical channel portions VC included in the one channel layer 120. From among the plurality of conductive contact patterns 150, the first conductive contact pattern and the second conductive contact pattern may be spaced apart from one another in the second lateral direction (Y direction).

A plurality of capacitor structures CAP may be arranged on the plurality of conductive contact patterns 150. An etch stop film 162 and an interlayer insulating film 170 may be sequentially stacked on the plurality of conductive contact patterns 150 and the upper insulating film 146, and each of the plurality of capacitor structures CAP may pass through the interlayer insulating film 170 and the etch stop film 162 in the vertical direction (Z direction) and be connected to a selected one of the plurality of conductive contact patterns 150. The etch stop film 162 may include a silicon nitride film, and the interlayer insulating film 170 may include a silicon oxide film. A structure of each of the plurality of capacitor structures CAP is not limited to that illustrated in FIG. 2 and may be variously modified and changed within the scope of the disclosed concepts.

According to the semiconductor device 100 described with reference to FIGS. 1 to 4, the silicon-containing metal nitride film BLP may be locally between the channel layer 120 employing an oxide semiconductor material and the bit line BL connected to the channel layer 120. The silicon-containing metal nitride film BLP may have a sufficiently small thickness to ensure electrical connection between the channel layer 120 and the bit line BL. In addition, the silicon-containing metal nitride film BLP may be locally located only between the contact surface BLC of the bit line BL and the channel layer 120. Accordingly, the bit line BL may be prevented from being undesirably oxidized during the formation of the channel layer 120 by using the silicon-containing metal nitride film BLP having a minimum volume. In addition, during the manufacture of the semiconductor device 100 or after the semiconductor device 100 is completed, hydrogen may be prevented from being undesirably diffused into the channel layer 120 through the bit line BL. Therefore, the electrical characteristics and reliability of the semiconductor device 100 may improve.

FIG. 6 is a cross-sectional view of a semiconductor device 200 according to embodiments. FIG. 6 illustrates an enlarged cross-sectional configuration of a portion of the semiconductor device 200, which corresponds to portion “EX1” of FIG. 2. In FIG. 6, the same reference numerals are used to denote the same elements as in FIGS. 1 to 4, and thus, repeated descriptions thereof are omitted.

Referring to FIG. 6, the semiconductor device 200 may substantially have the same configuration as the semiconductor device 100 described with reference to FIGS. 1 to 4. However, the semiconductor device 200 may include a mold insulating pattern 210. The mold insulating pattern 210 may substantially have the same configuration as the mold insulating pattern 110 described with reference to FIGS. 1, 2, and 4. The mold insulating pattern 210 may include a first mold insulating pattern 210A, a second mold insulating pattern 210B, and a third mold insulating pattern 210C, which are sequentially stacked on the bit line BL in a vertical direction (Z direction). The first mold insulating pattern 210A, the second mold insulating pattern 210B, and the third mold insulating pattern 210C may each include a silicon oxide film, a silicon nitride film, or a combination thereof. For example, the first mold insulating pattern 210A and the third mold insulating pattern 210C may each include a silicon nitride film, and the second mold insulating pattern 210B may include a silicon oxide film. In embodiments, the third mold insulating pattern 210C may be omitted in the mold insulating pattern 210. In this case, the mold insulating pattern 210 may include the first mold insulating pattern 210A and the second mold insulating pattern 210B, the first mold insulating pattern 210A may include a silicon nitride film, and the second mold insulating pattern 210B may include a silicon oxide film.

The first mold insulating pattern 210A, the second mold insulating pattern 210B, and the third mold insulating pattern 210C included in the mold insulating pattern 210 may respectively and substantially have the same configurations as the first mold insulating pattern 110A, the second mold insulating pattern 110B, and the third mold insulating pattern 110C described with reference to FIGS. 1, 2, and 4. However, each of the first mold insulating pattern 210A, the second mold insulating pattern 210B, and the third mold insulating pattern 210C included in the mold insulating pattern 210 may be in contact with sidewalls of a pair of vertical channel portions VC included in a channel layer 120. In each of the first mold insulating pattern 210A, the second mold insulating pattern 210B, and the third mold insulating pattern 210C included in the mold insulating pattern 210, a partial region adjacent to the vertical channel portion VC of the channel layer 120 may overlap a silicon-containing metal nitride film BLP in the vertical direction (Z direction). The first mold insulating pattern 210A may have surfaces in contact with a sidewall BLPS and a top surface of the silicon-containing metal nitride film BLP.

In the semiconductor device 200, a vertical level LT21 of the non-contact surface BLN of the bit line BL may be lower than a vertical level LT22 of a surface of the silicon-containing metal nitride film BLP, which is in contact with a horizontal channel portion HC of the channel layer 120. In the second lateral direction (Y direction), a width W21 of the silicon-containing metal nitride film BLP may be greater than a width W22 of the horizontal channel portion HC of the channel layer 120 and less than a width of the bit line BL. From among both sidewalls of the silicon-containing metal nitride film BLP in the second lateral direction (Y direction), the sidewall BLPS adjacent to the mold insulating pattern 210 may protrude toward the mold insulating pattern 210 in the second lateral direction (Y direction) further than an outer surface of the vertical channel portion VC of the channel layer 120, which faces the mold insulating pattern 210. In the semiconductor device 200, a first thickness from a contact surface BLC of the bit line BL to a bottom surface of the bit line BL in the vertical direction (Z direction) may be less than a second thickness from the non-contact surface BLN of the bit line BL to the bottom surface of the bit line BL in the vertical direction (Z direction).

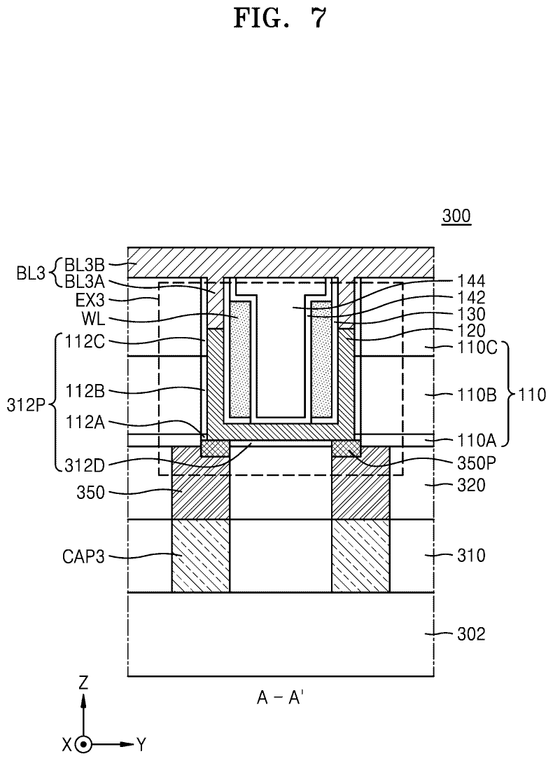

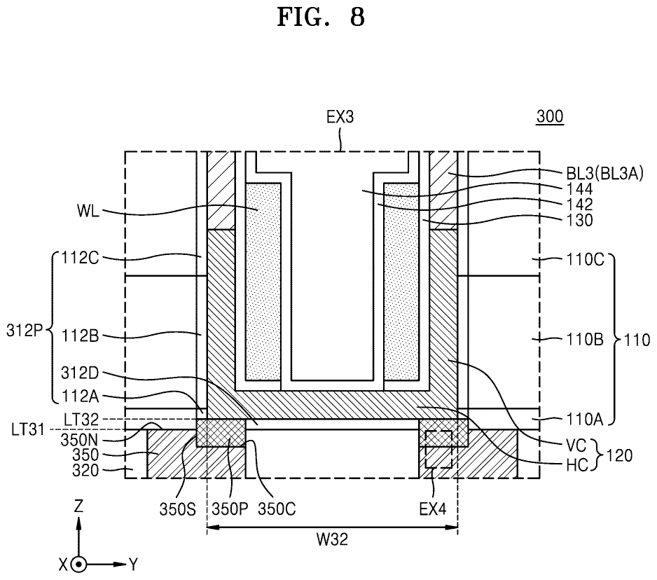

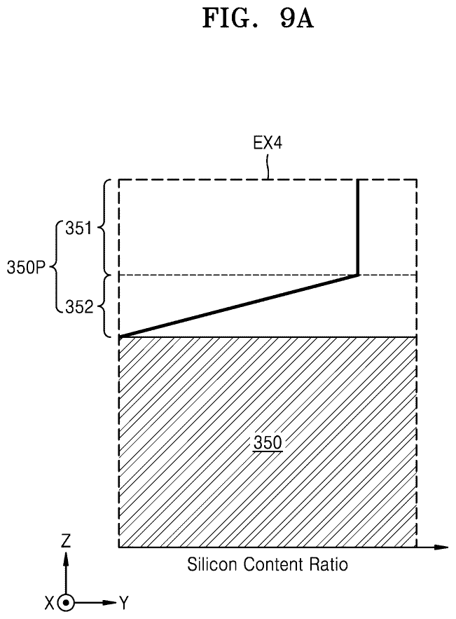

FIG. 7 is a cross-sectional view of a semiconductor device 300 according to embodiments. FIG. 7 illustrates a cross-sectional configuration of a portion of the semiconductor device 300, which corresponds to a cross-section taken along line A-A′ of FIG. 1. FIG. 8 is an enlarged cross-sectional view of a portion “EX3” in FIG. 7. In FIGS. 7 and 8, the same reference numerals are used to denote the same elements as in FIGS. 1 to 4, and thus, repeated descriptions thereof are omitted.

Referring to FIGS. 7 and 8, the semiconductor device 300 may substantially have the same configuration as the semiconductor device 100 described with reference to FIGS. 1 to 4. However, the semiconductor device 300 may include a substrate 302, a plurality of capacitor structures CAP3 arranged on the substrate 302, and a plurality of conductive contact patterns 350 arranged on the plurality of capacitor structures CAP3 and connected to the plurality of capacitor structures CAP3. A structure of each of the plurality of capacitor structures CAP3 is not limited to that illustrated in FIG. 7 and may be variously modified and changed within the scope of the disclosed concepts.

The substrate 302 may substantially have the same configuration as the substrate 102 described with reference to FIGS. 2 and 3. A first insulating layer 310 may be arranged adjacent to the capacitor structure CAP3 on the substrate 302. In embodiments, the first insulating layer 310 may include a silicon nitride film, a silicon oxide film, a silicon oxynitride film, or a combination thereof.

Each of the plurality of conductive contact patterns 350 may be electrically connected to an electrode included in the capacitor structure CAP3. In a view from above, the plurality of conductive contact patterns 350 may each have various shapes, such as a circle, an ellipse, a rectangle, a square, a rhombus, and a hexagon. The plurality of conductive contact patterns 350 may each include a metal-containing film. In embodiments, the plurality of conductive contact patterns 350 may each include Ti, TiN, Ta, TaN, Mo, Ru, W, WN, Co, Ni, TiSi, TiSiN, WSi, WSiN, TaSi, TaSiN, RuTiN, CoSi, NiSi, or a combination thereof. In embodiments, the plurality of conductive contact patterns 350 may each include a conductive metal nitride film. For example, the plurality of conductive contact patterns 350 may include TiN, without being limited thereto. As used herein, the plurality of conductive contact patterns 350 may each be referred to as a metal-containing contact pattern or a second conductive member. The plurality of conductive contact patterns 350 may be insulated from one another by a second insulating layer 320. The second insulating layer 320 may include a silicon nitride film, a silicon oxide film, a silicon oxynitride film, or a combination thereof.

A plurality of silicon-containing metal nitride films 350P may be between a horizontal channel portion HC of a channel layer 120 and the plurality of conductive contact patterns 350 adjacent thereto. Each of the plurality of silicon-containing metal nitride films 350P may have a surface (referred to as a first surface) in contact with a contact surface 350C of the conductive contact pattern 350, which is adjacent to the channel layer 120, and a surface (referred to as a second surface) in contact with the horizontal channel portion HC of the channel layer 120.

The plurality of silicon-containing metal nitride films 350P may have a tunneling-permissive thickness to enable electrical connection between the conductive contact pattern 350 and the channel layer 120. For example, each of the plurality of silicon-containing metal nitride films 350P may have a thickness of about 10 Å to about 50 Å in a vertical direction (Z direction), without being limited thereto.

When the conductive contact pattern 350 includes a TiN film, the silicon-containing metal nitride film 350P may include a TiSiN film. In the TiSiN film included in the silicon-containing metal nitride film 350P, an atomic ratio of Si/(Ti+Si) may be within a range of about 0.2 to about 1.0.

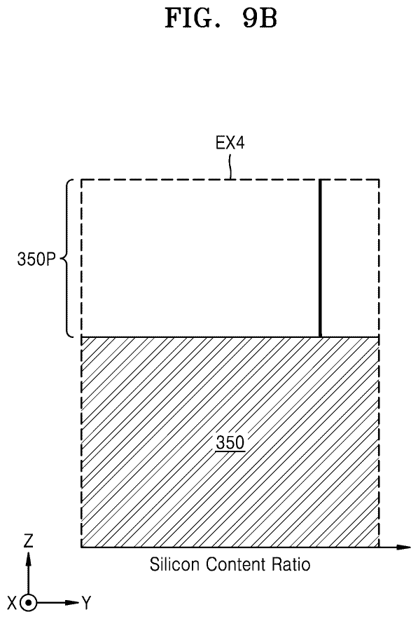

FIGS. 9A and 9B are each a graph for explaining an example of a content ratio of silicon atoms in the silicon-containing metal nitride film 350P. FIGS. 9A and 9B each illustrate a variation in the content ratio of silicon atoms in a partial region of the silicon-containing metal nitride film 350P, of region “EX4” of FIG. 8.

In embodiments, as shown in FIG. 9A, a content ratio of silicon (Si) atoms in the silicon-containing metal nitride film 350P may be variable in the vertical direction (Z direction). The silicon-containing metal nitride film 350P may include a first portion 351 in which a content ratio of silicon (Si) atoms in the silicon-containing metal nitride film 350P is constant regardless of a distance from the conductive contact pattern 350 in the vertical direction (Z direction) and a second portion 352 in which a content ratio of silicon (Si) atoms in the silicon-containing metal nitride film 350P gradually increases in a direction away from the conductive contact pattern 350 in the vertical direction (Z direction). In the silicon-containing metal nitride film 350P, the second portion 352 may be in contact with the conductive contact pattern 350, and the first portion 351 may be spaced apart from the conductive contact pattern 350 with the second portion 352 therebetween in the vertical direction (Z direction).

In embodiments, as shown in FIG. 9B, a content ratio of silicon (Si) atoms in the silicon-containing metal nitride film 350P may be constant in the vertical direction (Z direction). That is, a content ratio of silicon (Si) atoms in the silicon-containing metal nitride film 350P may be constant regardless of the distance from the conductive contact pattern 350 in the vertical direction (Z direction).

As shown in FIG. 8, each of the plurality of conductive contact patterns 350 may include a non-contact surface 350N in contact with a mold insulating pattern 110. A first thickness from a contact surface 350C of the conductive contact pattern 350 to a bottom surface of the conductive contact pattern 350 in the vertical direction (Z direction) may be less than a second thickness from the non-contact surface 350N of the conductive contact pattern 350 to the bottom surface of the conductive contact pattern 350 in the vertical direction (Z direction). As used herein, the bottom surface of the conductive contact pattern 350 refers to a surface facing a substrate (refer to 302 in FIG. 7), from among surfaces of the conductive contact pattern 350.

A vertical level LT31 of the non-contact surface 350N of the conductive contact pattern 350 may be closer to the substrate 302 than a vertical level LT32 of a surface of the silicon-containing metal nitride film 350P, which is in contact with a horizontal channel portion HC of a channel layer 120. In the present embodiment, a vertical level refers to a distance from the substrate 302 in the vertical direction (Z direction).

In a second lateral direction (Y direction), a width of the silicon-containing metal nitride film 350P may be less than a width W32 of the horizontal channel portion HC of the channel layer 120. In the second lateral direction (Y direction), a sidewall 350S adjacent to the mold insulating pattern 110, from among both sidewalls of the silicon-containing metal nitride film 350P, may protrude toward the mold insulating pattern 110 in the second lateral direction (Y direction) further than an outer surface of a vertical channel portion VC of the channel layer 120, which faces the mold insulating pattern 110.

The plurality of conductive contact patterns 350 may include a pair of conductive contact patterns 350, which are adjacent to the horizontal channel portion HC included in one channel layer 120 and spaced apart from one another in the second lateral direction (Y direction). The pair of conductive contact patterns 350 may include a conductive contact pattern 350 (referred to as a first conductive contact pattern), which is adjacent to a first portion of the horizontal channel portion HC included in the one channel layer 120, and a conductive contact pattern 350 (referred to as a second conductive contact pattern), which is adjacent to a second portion spaced apart from the first portion, of the horizontal channel portion HC included in the one channel layer 120, and is spaced apart from the first conductive contact pattern in the second lateral direction (Y direction).

The plurality of silicon-containing metal nitride films 350P may include a pair of silicon-containing metal nitride films 350P in contact with the horizontal channel portion HC included in one channel layer 120. The pair of silicon-containing metal nitride films 350P may include a silicon-containing metal nitride film 350P (referred to as a first silicon-containing metal nitride film), which has a surface in contact with the contact surface 350C of the conductive contact pattern 350) (or the first conductive contact pattern), which is adjacent to the first portion of the horizontal channel portion HC included in the one channel layer 120, and a surface in contact with the first portion, and a silicon-containing metal nitride film 350P (referred to as a second silicon-containing metal nitride film) having a surface in contact with the contact surface 350C of the conductive contact pattern 350) (or the second conductive contact pattern), which is adjacent to the second portion of the horizontal channel portion HC included in the one channel layer 120, and a surface in contact with the second portion. The first silicon-containing metal nitride film and the second silicon-containing metal nitride film may be spaced apart from one another in the second lateral direction (Y direction). In the second lateral direction (Y direction), a width of each of the first silicon-containing metal nitride film and the second silicon-containing metal nitride film may be less than a width of each of a pair of conductive contact patterns 350) (the first conductive contact pattern and the second conductive contact pattern) adjacent thereto.

In the second lateral direction (Y direction), an insulating liner structure 312P may be between the mold insulating pattern 110 and the vertical channel portion VC of the channel layer 120. The insulating liner structure 312P may have a surface (referred to as a first surface) in contact with the mold insulating pattern 110 and a surface (referred to as a second surface) in contact with the vertical channel portion VC of the channel layer 120.

A portion of the insulating liner structure 312P may be arranged to overlap the silicon-containing metal nitride film 350P in the vertical direction (Z direction). The insulating liner structure 312P may include a first insulating liner portion 112A, a second insulating liner portion 112B, and a third insulating liner portion 112C, which are sequentially arranged on a top surface of the silicon-containing metal nitride film 350P in the vertical direction (Z direction). The first insulating liner portion 112A, the second insulating liner portion 112B, and the third insulating liner portion 112C may overlap the silicon-containing metal nitride film 350P in the vertical direction (Z direction).

The insulating liner structure 312P may further include a fourth insulating liner portion 312D, which is in contact with a bottom surface of the horizontal channel portion HC between the pair of silicon-containing metal nitride films 350P in contact with the horizontal channel portion HC of one channel layer 120. Detailed configurations of the first insulating liner portion 112A, the second insulating liner portion 112B, and the third insulating liner portion 112C are the same as those described with reference to FIGS. 2 and 4.

The fourth insulating liner portion 312D may be in contact with a top surface of the second insulating layer 320. When the second insulating layer 320 includes a silicon nitride film, the fourth insulating liner portion 312D may include a silicon nitride film. Here, a content ratio of nitrogen atoms in the silicon nitride film included in the second insulating layer 320 may be higher than a content ratio of nitrogen atoms in the silicon nitride film included in the fourth insulating liner portion 312D. When the second insulating layer 320 includes a silicon oxide film, the fourth insulating liner portion 312D may include a silicon oxide film. Here, a content ratio of oxygen atoms in the silicon oxide film included in the second insulating layer 320 may be higher than a content ratio of oxygen atoms in the silicon oxide film included in the fourth insulating liner portion 312D.

A plurality of bit lines BL3 may be arranged on the plurality of channel layers 120. Each of the plurality of bit lines BL3 may be connected to a selected one of the plurality of channel layers 120. As used herein, the bit line BL3 may be referred to as a metal-containing conductive line or a first conductive member. Each of the plurality of bit lines BL3 may be in contact with a top surface of each of a pair of vertical channel portions VC included in the channel layer 120 adjacent thereto.

In the semiconductor device 300, the bit line BL3 may be spaced apart from the plurality of conductive contact patterns 350 with the channel layer 120 therebetween in the vertical direction (Z direction). In the semiconductor device 300, the vertical channel portion VC of each of the plurality of channel layers 120 may have an upper end in contact with the bit line BL3. The horizontal channel portion HC of each of the plurality of channel layers 120 may be spaced apart from the bit line BL3 with a pair of word lines WL therebetween in the vertical direction (Z direction).

The bit line BL3 may include a bit line contact portion BL3A and a bit line main portion BL3B. The bit line contact portion BL3A may be between the mold insulating pattern 110 and the gate dielectric film 130 and be in contact with the top surface of the vertical channel portion VC of the channel layer 120. The bit line main portion BL3B may be located on a top surface of the mold insulating pattern 110 and integrally connected to the bit line contact portion BL3A. In the second lateral direction (Y direction), a width of the bit line main portion BL3B may be greater than a width of the bit line contact portion BL3A. In the second lateral direction (Y direction), a width of the silicon-containing metal nitride film 350P may be less than a width of the bit line main portion BL3B of the bit line BL3. A constituent material of the bit line BL3 is the same as a constituent material of the bit line BL described with reference to FIGS. 1 to 4.

According to the semiconductor device 300 described with reference to FIGS. 7 and 8, the pair of silicon-containing metal nitride films 350P may be locally between the channel layer 120 employing an oxide semiconductor material and the pair of conductive contact patterns 350 connected to the channel layer 120. The pair of silicon-containing metal nitride films 350P may each have such a sufficiently small thickness as to ensure electrical connection between the channel layer 120 and the conductive contact pattern 350. In addition, the silicon-containing metal nitride film 350P may be locally located only between the contact surface 350C of the conductive contact pattern 350 and the channel layer 120. Accordingly, the conductive contact pattern 350 may be prevented from being undesirably oxidized during the formation of the channel layer 120 by using the silicon-containing metal nitride film 350P having a minimum volume. In addition, during the manufacture of the semiconductor device 300 or after the semiconductor device 300 is completed, hydrogen may be prevented from being undesirably diffused into the channel layer 120 through the conductive contact pattern 350. Therefore, the electrical characteristics and reliability of the semiconductor device 300 may improve.

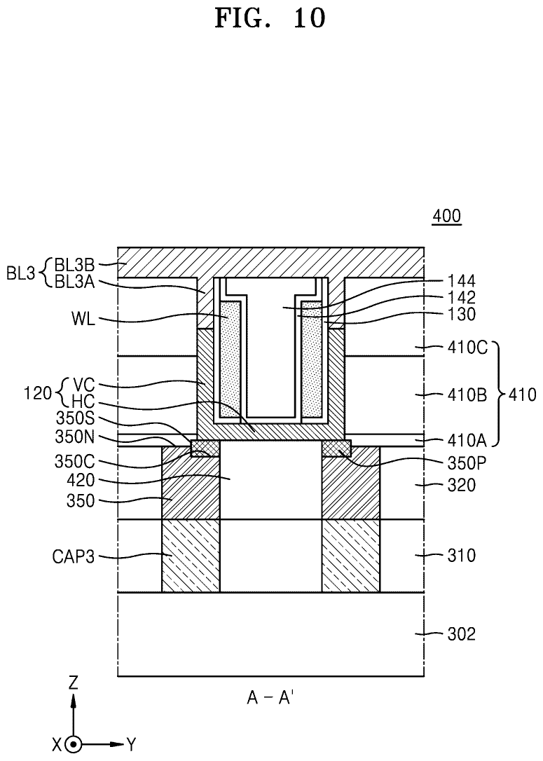

FIG. 10 is a cross-sectional view of a semiconductor device 400 according to embodiments. FIG. 10 illustrates a cross-sectional configuration of a portion of the semiconductor device 400, which corresponds to a cross-section taken along line A-A′ of FIG. 1. In FIG. 10, the same reference numerals are used to denote the same elements as in FIGS. 1 to 8, and thus, repeated descriptions thereof are omitted.

Referring to FIG. 10, the semiconductor device 400 may substantially have the same configuration as the semiconductor device 300 described with reference to FIGS. 7 and 8. However, the semiconductor device 400 may include a mold insulating pattern 410. The mold insulating pattern 410 may substantially have the same configuration as the mold insulating pattern 110 described with reference to FIGS. 1, 2, and 4. The mold insulating pattern 410 may include a first mold insulating pattern 410A, a second mold insulating pattern 410B, and a third mold insulating pattern 410C, which are sequentially stacked on the second insulating layer 320 and the plurality of conductive contact patterns 350 in a vertical direction (Z direction). The first mold insulating pattern 410A, the second mold insulating pattern 410B, and the third mold insulating pattern 410C may each include a silicon oxide film, a silicon nitride film, or a combination thereof. For example, the first mold insulating pattern 410A and the third mold insulating pattern 410C may each include a silicon nitride film, and the second mold insulating pattern 410B may include a silicon oxide film. In embodiments, the third mold insulating pattern 410C may be omitted in the mold insulating pattern 410. In this case, the mold insulating pattern 410 may include the first mold insulating pattern 410A and the second mold insulating pattern 410B, the first mold insulating pattern 410A may include a silicon nitride film, and the second mold insulating pattern 410B may include a silicon oxide film.

The first mold insulating pattern 410A, the second mold insulating pattern 410B, and the third mold insulating pattern 410C included in the mold insulating pattern 410 may respectively and substantially have the same configurations as the first mold insulating pattern 110A, the second mold insulating pattern 110B, and the third mold insulating pattern 110C described with reference to FIGS. 7 and 8. However, each of the first mold insulating pattern 410A, the second mold insulating pattern 410B, and the third mold insulating pattern 410C included in the mold insulating pattern 410 may be in contact with sidewalls of a pair of vertical channel portions VC included in a channel layer 120. In each of the first mold insulating pattern 410A, the second mold insulating pattern 410B, and the third mold insulating pattern 410C included in the mold insulating pattern 410, a partial region adjacent to the vertical channel portion VC of the channel layer 120 may overlap the silicon-containing metal nitride film 350P in the vertical direction (Z direction).

In the semiconductor device 400, from among both sidewalls of the silicon-containing metal nitride film 350P in the second lateral direction (Y direction), a sidewall 350S adjacent to the mold insulating pattern 410 may protrude toward the mold insulating pattern 410 in the second lateral direction (Y direction) further than an outer surface of the vertical channel portion VC of the channel layer 120, which is in contact with the mold insulating pattern 410. The first mold insulating pattern 410A may have surfaces in contact with the sidewall 350S and a top surface of the silicon-containing metal nitride film 350P.

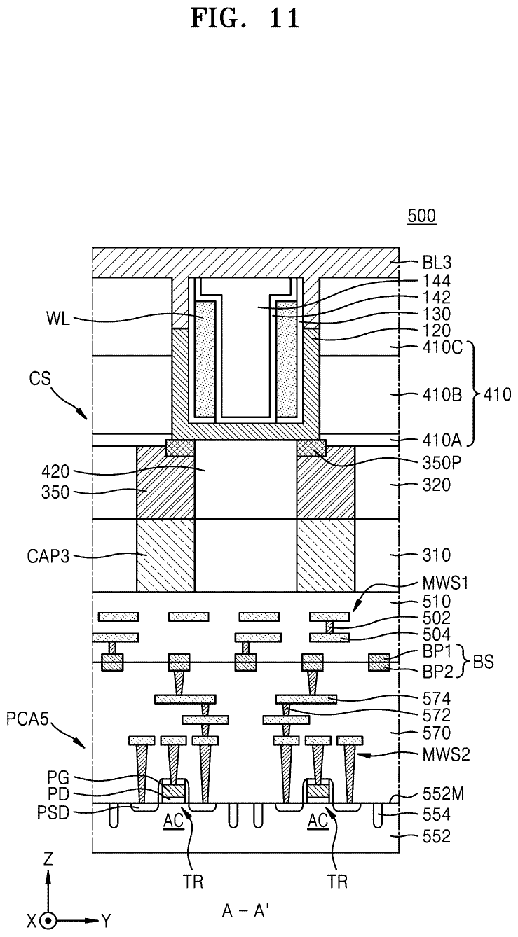

FIG. 11 is a cross-sectional view of a semiconductor device 500 according to embodiments. FIG. 11 illustrates a cross-sectional configuration of a portion of the semiconductor device 500, which corresponds to a cross-section taken along line A-A′ of FIG. 1. In FIG. 11, the same reference numerals are used to denote the same elements as in FIGS. 1 to 10, and thus, repeated descriptions thereof are omitted.

Referring to FIG. 11, the semiconductor device 500 may substantially have the same configuration as the semiconductor device 400 described with reference to FIG. 10. However, the semiconductor device 500 may further include a peripheral circuit structure PCA5, which is spaced apart from a channel layer 120 in a vertical direction (Z direction) with a plurality of conductive contact patterns 350, a plurality of silicon-containing metal nitride films 350P, and a plurality of capacitor structures CAP3 therebetween. In a vertical direction (Z direction), the peripheral circuit structure PCA5 may be between a substrate 552 and a memory cell structure CS.

FIG. 11 illustrates a case in which the memory cell structure CS has the same structure as a structure arranged on the substrate 302, which has been described with reference to FIG. 10.

However, the disclosed concepts are not limited thereto. For example, the memory cell structure CS may have the same structure as a structure arranged on the substrate 302, which has been described with reference to FIGS. 7 and 8.

The memory cell structure CS of the semiconductor device 500 may include a multilayered wiring structure MWS1 between the peripheral circuit structure PCA5 and a structure including the plurality of capacitor structures CAP3 and a first insulating layer 310. The multilayered wiring structure MWS1 may include a plurality of contact plugs 502 and a plurality of conductive lines 504. The multilayered wiring structure MWS1 may be covered by an interlayer insulating film 510. The interlayer insulating film 510 may include a silicon oxide film, a silicon nitride film, a silicon oxynitride film (SiON film), a silicon oxycarbonitride film (SiOCN film), or a combination thereof.

The multilayered wiring structure MWS1 may further include a plurality of first bonding pads BP1. The plurality of first bonding pads BP1 may be arranged along a surface of the interlayer insulating film 510, which faces the peripheral circuit structure PCA5. The surface of the interlayer insulating film 510, which faces the peripheral circuit structure PCA5, may be coplanar with a surface of each of the plurality of first bonding pads BP1, which faces the peripheral circuit structure PCA5. Each of the plurality of first bonding pads BP1 may be electrically connected to at least one of the plurality of contact plugs 502 and the plurality of conductive lines 504. The plurality of capacitor structures CAP3 may be electrically connected to at least one of the plurality of contact plugs 502 and the plurality of conductive lines 504.

The peripheral circuit structure PCA5 may include a substrate 552, a plurality of circuits formed on the substrate 552, and a multilayered wiring structure MWS2 configured to connect the plurality of circuits to one another or connect the plurality of circuits to a plurality of memory cells included in the memory cell structure CS.

The substrate 552 may include a silicon substrate. An active region AC may be defined by a device isolation film 554 in the substrate 552. A plurality of transistors TR that constitute the plurality of circuits may be arranged on the active region AC. Each of the plurality of transistors TR may include a gate dielectric film PD and a gate PG, which are sequentially stacked on the substrate 552, a plurality of ion implantation regions PSD formed in the active region AC on both sides of the gate PG. Each of the plurality of ion implantation regions PSD may constitute a source region or a drain region of the transistor TR.

The multilayered wiring structure MWS2 included in the peripheral circuit structure PCA5 may include a plurality of contact plugs 572 and a plurality of conductive lines 574. At least some of the plurality of conductive lines 574 may be configured to be electrically connectable to the transistor TR. The plurality of contact plugs 572 may be configured to connect the plurality of transistors TR to some selected ones of the plurality of conductive lines 574. The plurality of transistors TR and the multilayered wiring structure MWS2 included in the peripheral circuit structure PCA5 may be covered by an interlayer insulating film 570. The interlayer insulating film 570 may include a silicon oxide film, a silicon nitride film, a silicon oxynitride film (SiON film), a silicon oxycarbonitride film (SiOCN film), or a combination thereof.

The multilayered wiring structure MWS2 may further include a plurality of second bonding pads BP2. The plurality of second bonding pads BP2 may be arranged along a surface of the interlayer insulating film 570, which faces the memory cell structure CS. The surface of the interlayer insulating film 570, which faces the memory cell structure CS, may be coplanar with a surface of each of the plurality of second bonding pads BP2, which faces the memory cell structure CS. Each of the plurality of second bonding pads BP2 may be electrically connected to at least one of the plurality of contact plugs 572 and the plurality of conductive lines 574.

In embodiments, the semiconductor device 500 may have a chip-to-chip (C2C) structure. The memory cell structure CS may be connected to the peripheral circuit structure PCA5 by bonding the plurality of first bonding pads BP1 to the plurality of second bonding pads BP2. The plurality of first bonding pads BP1 and the plurality of second bonding pads BP2 may constitute a plurality of bonding structures BS. In embodiments, each of the plurality of first bonding pads BP1 and the plurality of second bonding pads BP2 included in the bonding structure BS may include copper (Cu), aluminum (Al), or tungsten (W). The plurality of transistors TR, the plurality of contact plugs 572, and the plurality of conductive lines 574 included in the peripheral circuit structure PCA5 may constitute the plurality of circuits. Each of the plurality of transistors TR may be configured to be electrically connectable to the plurality of memory cells included in the memory cell structure CS through the multilayered wiring structure MWS2 and the plurality of bonding structures BS.

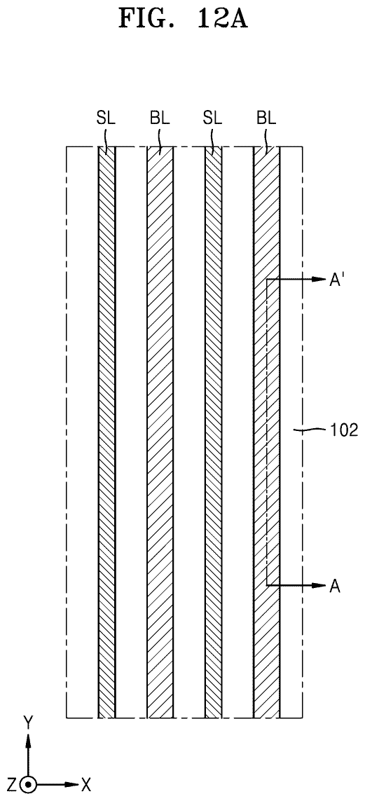

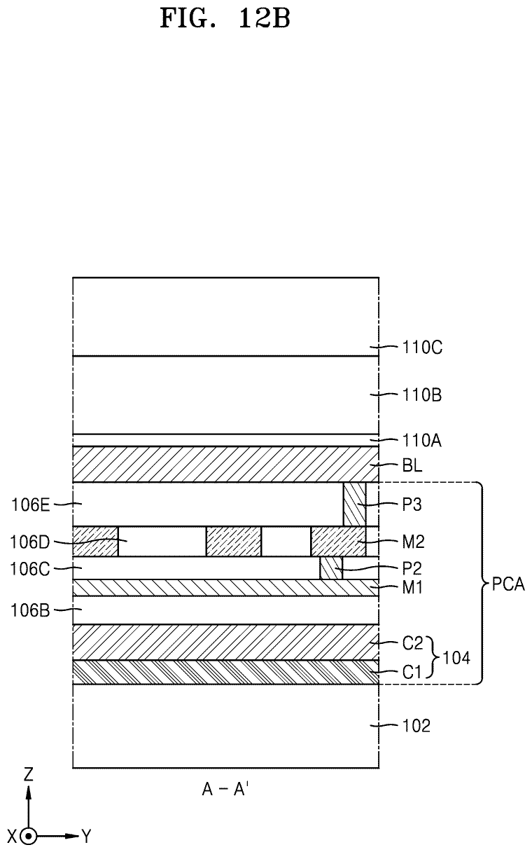

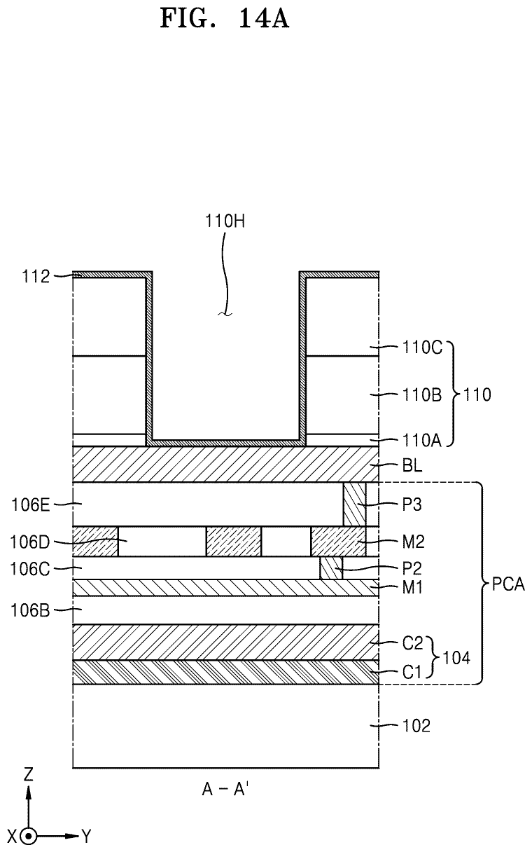

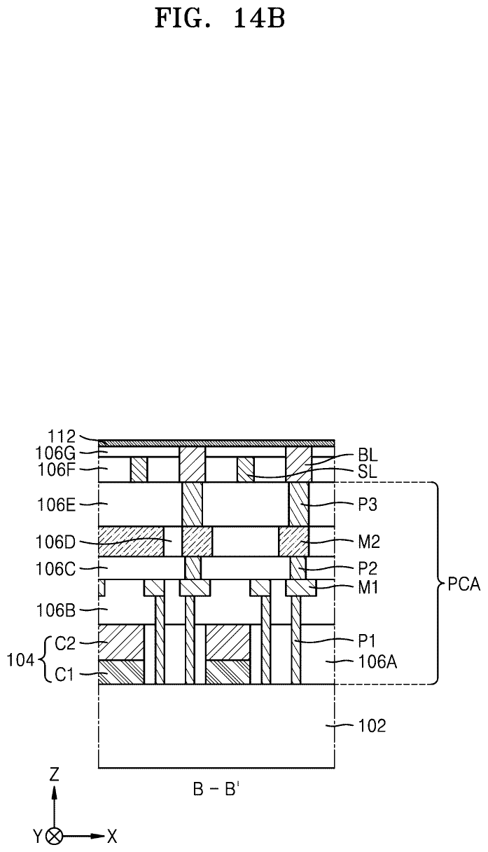

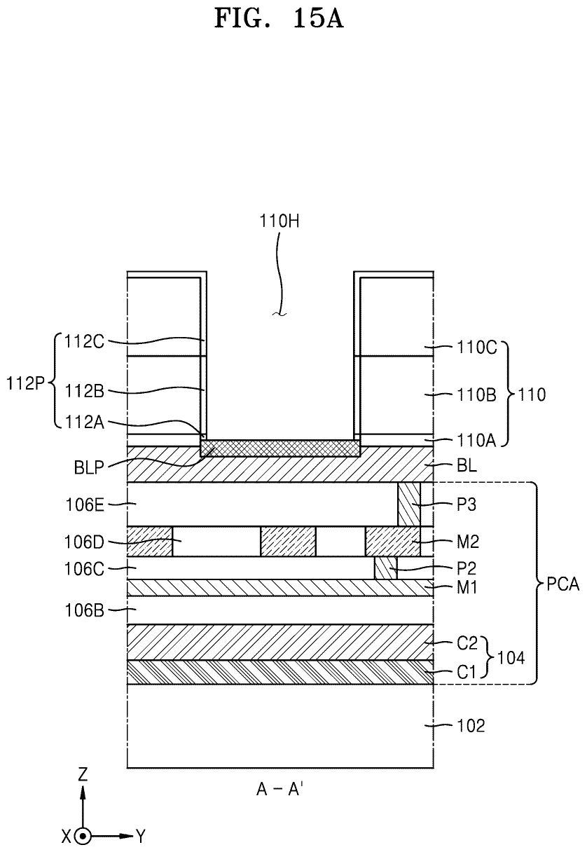

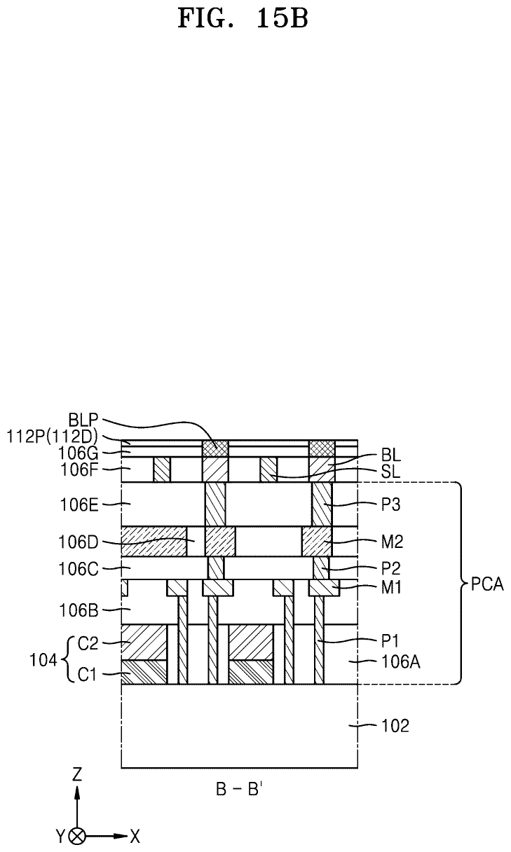

FIGS. 12A to 20 are diagrams of a process sequence of a method of manufacturing a semiconductor device, according to embodiments. More specifically, FIGS. 12A, 13A, and 18A are plan layout diagrams of some components, according to the process sequence, which illustrate a method of manufacturing a semiconductor device. FIGS. 12B, 13B, 14A, 15A, 16, 17, 18B, 19, and 20 are cross-sectional views of a portion corresponding to line A-A′ of FIG. 1, according to the process sequence. FIGS. 14B and 15B are cross-sectional views of a portion corresponding to line B-B′ of FIG. 1, according to the process sequence. An example of a method of manufacturing the semiconductor device 100 shown in FIGS. 1 to 4 is described with reference to FIGS. 12A to 20. In FIGS. 12A to 20, the same reference numerals are used to denote the same elements as in FIGS. 1 to 4, and thus, repeated descriptions thereof are omitted.

Referring to FIGS. 12A and 12B, a plurality of peripheral circuits including a plurality of core circuits 104, a plurality of conductive plugs (e.g., P1, P2, and P3), a plurality of wiring layers (e.g., M1 and M2), and a plurality of interlayer insulating films (e.g., 106A, 106B, 106C, 106D, and 106E) may be formed on a substrate 102, and thus, a peripheral circuit structure PCA may be formed on the substrate 102. Thereafter, an interlayer insulating film (refer to 106F in FIG. 3) and a plurality of shield structures SL passing through the interlayer insulating film 106F may be formed on the peripheral circuit structure PCA, and an interlayer insulating film 106G may be formed to cover the interlayer insulating film 106F and the plurality of shield structures SL, and a plurality of bit lines BL may be formed to pass through the interlayer insulating films (refer to 106F and 106G in FIG. 3). Thereafter, a first mold insulating pattern 110A, a second mold insulating pattern 110B, and a third mold insulating pattern 110C may be sequentially formed on the plurality of bit lines BL.

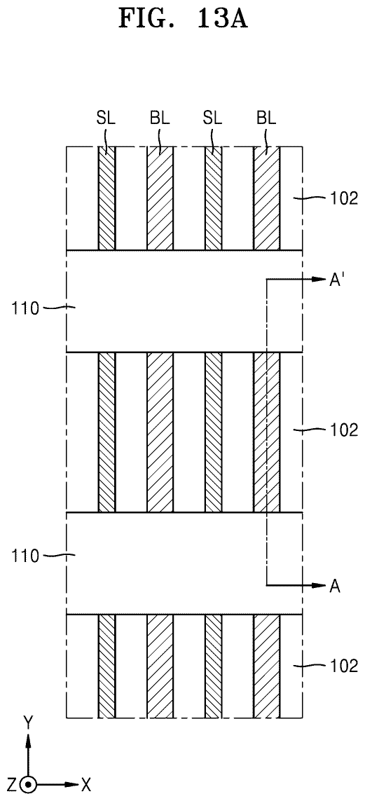

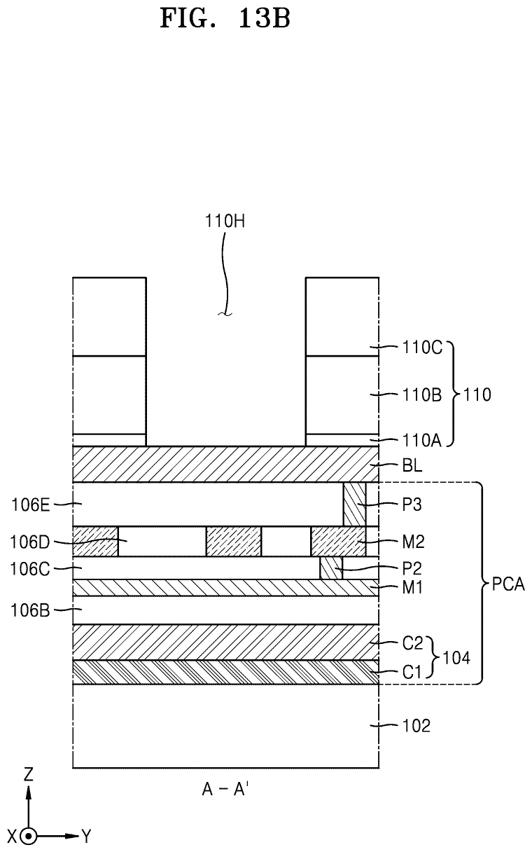

Referring to FIGS. 13A and 13B, a plurality of openings 110H may be formed to pass through the first mold insulating pattern 110A, the second mold insulating pattern 110B, and the third mold insulating pattern 110C. Thus, a mold insulating pattern 110 including the first mold insulating pattern 110A, the second mold insulating pattern 110B, and the third mold insulating pattern 110C may be formed to define the plurality of openings 110H. Respective partial regions of the plurality of bit lines BL may be exposed through the plurality of openings 110H, and the mold insulating pattern 110 may cover other respective partial regions of the plurality of bit lines BL. Each of the plurality of openings 110H defined by the mold insulating pattern 110 may provide a transistor region (refer to TRR in FIG. 1).

Referring to FIGS. 14A and 14B, a silicon-containing liner 112 may be formed on the resultant structure of FIGS. 13A and 13B. The silicon-containing liner 112 may include a portion in contact with the bit line BL inside the opening 110H, a portion in contact with the mold insulating pattern 110, and a portion in contact with the interlayer insulating film 106G. In embodiments, the silicon-containing liner 112 may include a Si liner.

To form the silicon-containing liner 112, an atomic layer deposition (ALD) process may be performed by using a Si precursor. In embodiments, the silicon-containing liner 112 may be formed to have a uniform thickness, which is selected in a range of about 10 Å to about 50 Å. To form the silicon-containing liner 112, monosilane (SiH₄), dichlorosilane (DCS), tetraethoxysilane (TEOS), tetramethylsilane (TMS), hexachlorodisilane (HCD), disilane (Si₂H₆), hexamethyldisilane (HMDS), or trichlorosilane (TCS) may be used as the Si precursor, without being limited thereto.

Referring to FIGS. 15A and 15B, the resultant structure of FIGS. 14A and 14B, which includes the silicon-containing liner 112, may be annealed to induce a surface reaction between the silicon-containing liner 112 and the bit line BL at a portion where the silicon-containing liner 112 is in contact with the bit line BL. The annealing process may be performed at a temperature selected in a range of about 100 °C to about 600 °C, without being limited thereto.

By annealing the resultant structure of FIGS. 14A and 14B, which includes the silicon-containing liner 112, a portion of the silicon-containing liner 112, which is in contact with the bit line BL, and a partial region of the bit line BL adjacent to the silicon-containing liner 112 may be changed into a silicon-containing metal nitride film BLP. In addition, due to the annealing process, a surface reaction may be induced between the silicon-containing liner 112 and each of the first mold insulating pattern 110A, the second mold insulating pattern 110B, and the third mold insulating pattern 110C of the mold insulating pattern 110 at a portion where the silicon-containing liner 112 is in contact with the mold insulating pattern 110, and a surface reaction may be induced between the silicon-containing liner 112 and the interlayer insulating film 106G at a portion where the silicon-containing liner 112 is in contact with the interlayer insulating film 106G. Thus, an insulating liner structure 112P including the first insulating liner portion 112A, the second insulating liner portion 112B, the third insulating liner portion 112C, and the fourth insulating liner portion 112D may be obtained from portions of the silicon-containing liner 112, which are in contact with the mold insulating pattern 110 and the interlayer insulating film 106G.

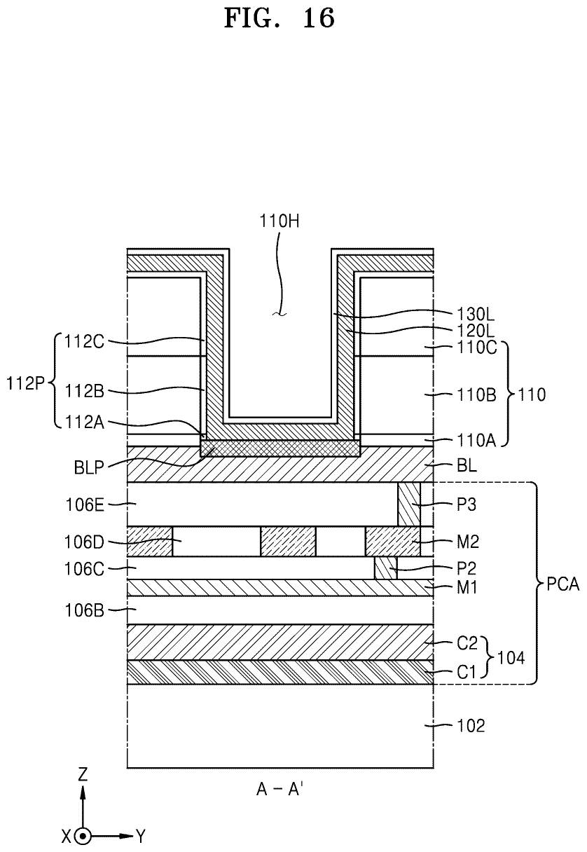

Referring to FIG. 16, in the resultant structure of FIGS. 15A and 15B, a preliminary channel layer 120L may be formed to conformally cover surfaces exposed at the plurality of openings 110H, and a preliminary gate dielectric film 130L may be formed to conformally cover the preliminary channel layer 120L.

The preliminary channel layer 120L may include an oxide semiconductor layer. The oxide semiconductor layer may include IGZO, Sn-IGZO, IWO, IZO, ZTO), ZnO, YZO, IGSO, InO, SnO, TiO, ZnON, MgZnO, ZrInZnO, HfInZnO, SnInZnO, SiInZnO, GaZnSnO, ZrZnSnO, or a combination thereof. For example, the preliminary channel layer 120L may include IGZO.

In embodiments, each of the preliminary channel layer 120L and the preliminary gate dielectric film 130L may be formed by using at least one of a chemical vapor deposition (CVD) process, a low-pressure CVD (LPCVD) process, a plasma-enhanced CVD (PECVD) process, a metal organic CVD (MOCVD) process, and an ALD process. In embodiments, each of the preliminary channel layer 120L and the preliminary gate dielectric film 130L may be formed to a thickness of about 1 nm to about 50 nm, without being limited thereto.

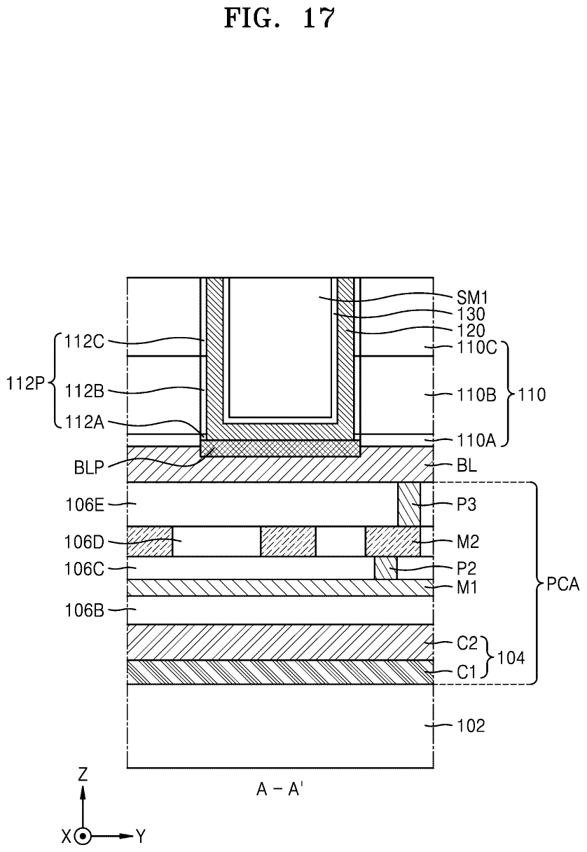

Referring to FIG. 17, in the resultant structure of FIG. 16, a sacrificial pattern SM1 covering the preliminary gate dielectric film 130L may be formed inside the opening 110H of the mold insulating pattern 110, and unnecessary portions of the preliminary channel layer 120L and the preliminary gate dielectric film 130L may be removed by using the sacrificial pattern SM1 as an etch mask. Thus, the preliminary channel layer 120L may be divided into a plurality of channel layers 120, and the preliminary gate dielectric film 130L may be divided into a plurality of gate dielectric films 130.

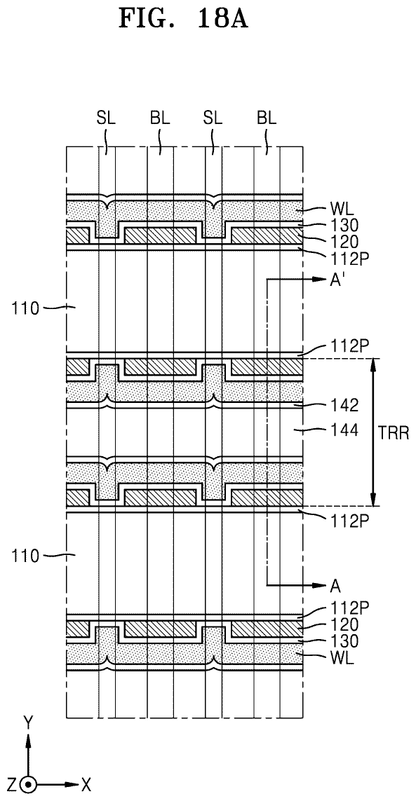

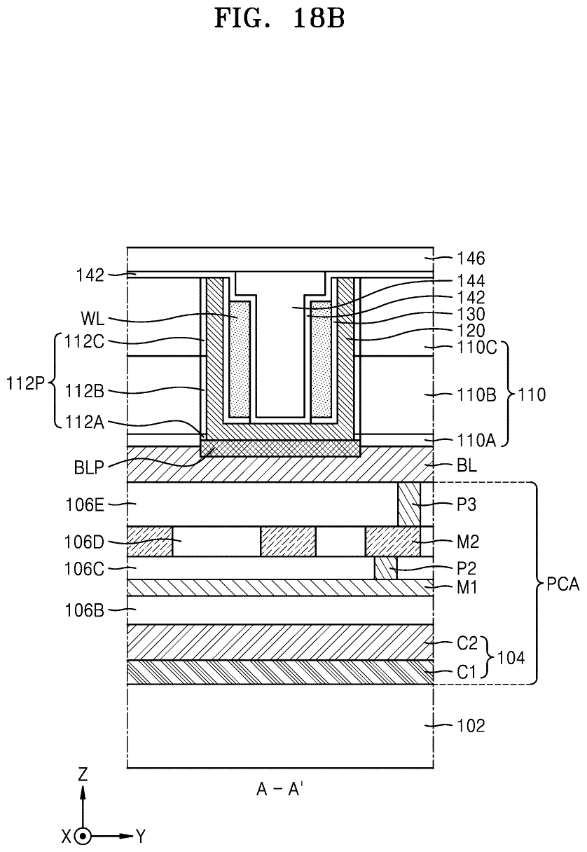

Referring to FIGS. 18A and 18B, in the resultant structure of FIG. 17, the sacrificial pattern SM1 may be removed to expose the gate dielectric film 130, and a plurality of word lines WL may be formed on the gate dielectric film 130 inside the opening 110H of the mold insulating pattern 110. The gate dielectric film 130 located between the two word lines WL inside the opening 110H may be partially removed during a patterning process of forming the plurality of word lines WL, and thus, a top surface of the channel layer 120 may be exposed between the two word lines WL located inside the opening 110H.

Thereafter, a lower insulating liner 142 and an upper insulating barrier wall 144 may be sequentially formed inside the opening 110H on the two word lines WL located inside the opening 110H. After the upper insulating barrier wall 144 is formed, a top surface of the upper insulating barrier wall 144 may be coplanar with a top surface of the lower insulating liner 142, which is located on a top surface of the mold insulating pattern 110. Afterwards, an upper insulating film 146 may be formed to cover the top surface of each of the lower insulating liner 142 and the upper insulating barrier wall 144.

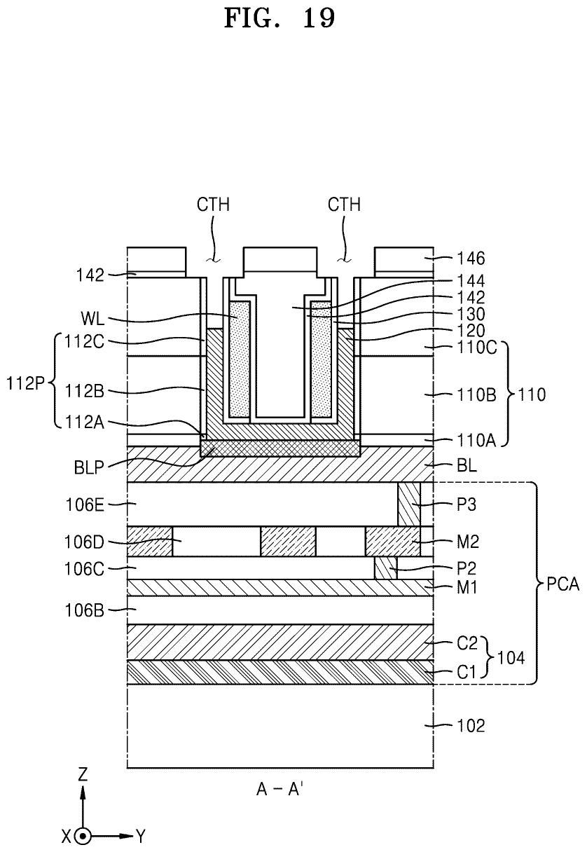

Referring to FIG. 19, a portion of the upper insulating barrier wall 144 exposed at an uppermost portion of the resultant structure of FIGS. 18A and 18B may be removed to expose the lower insulating liner 142. Subsequently, the exposed lower insulating liner 142 may be etched to expose an uppermost surface of the channel layer 120, and the channel layer 120 may be partially removed from the exposed uppermost surface of the channel layer 120 to form a plurality of contact spaces CTH. The plurality of contact spaces CTH may be formed by using a wet process, a dry process, or a combination thereof. For example, each of the plurality of channel layers 120 may be partially removed from the uppermost surface thereof by using a wet etching process.

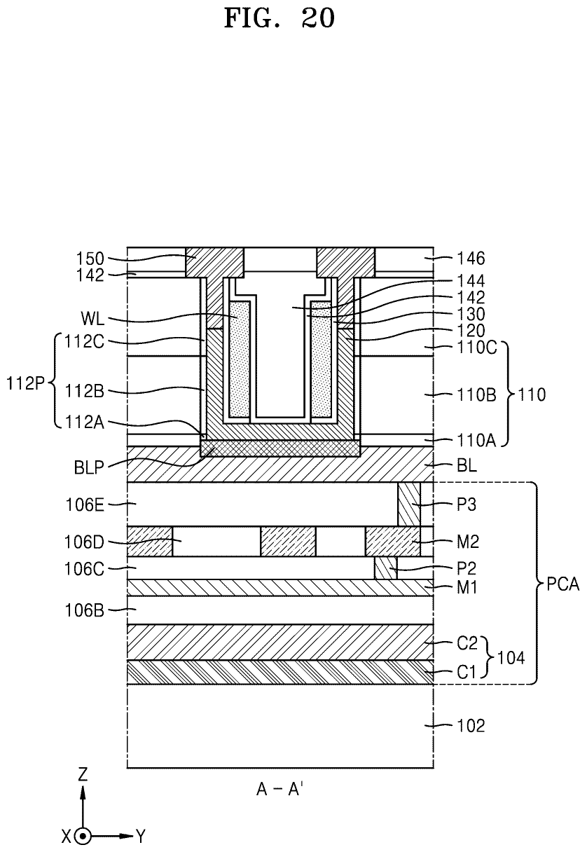

Referring to FIG. 20, in the resultant structure of FIG. 19, a plurality of conductive contact patterns 150 may be formed to fill the plurality of contact spaces CTH. Subsequently, as shown in FIGS. 2 and 3, an etch stop film 162 and an interlayer insulating film 170 may be formed on the resultant structure in which the plurality of conductive contact patterns 150 are formed, and a plurality of capacitor structures CAP may be formed to pass through the etch stop film 162 and the interlayer insulating film 170 and be connected to the plurality of conductive contact patterns 150. Thus, the semiconductor device 100 shown in FIGS. 1 to 4 may be manufactured.

To manufacture the semiconductor device 200 shown in FIG. 6, the processes described with reference to FIGS. 12A to 20 may be performed. However, in the process described with reference to FIGS. 15A and 15B, by controlling an annealing temperature and an annealing time for annealing the resultant structure of FIGS. 14A and 14B, which includes the silicon-containing liner 112, the diffusion of atoms may be induced between the first mold insulating pattern 110A, the second mold insulating pattern 110B, and the third mold insulating pattern 110C of the mold insulating pattern 110 and local regions of the silicon-containing liner 112 adjacent thereto. As a result, a mold insulating pattern 210 including the first mold insulating pattern 210A, the second mold insulating pattern 210B, and the third mold insulating pattern 210C may be obtained from the first mold insulating pattern 110A, the second mold insulating pattern 110B, and the third mold insulating pattern 110C of the mold insulating pattern 110 and local regions of the silicon-containing liner 112 adjacent thereto.

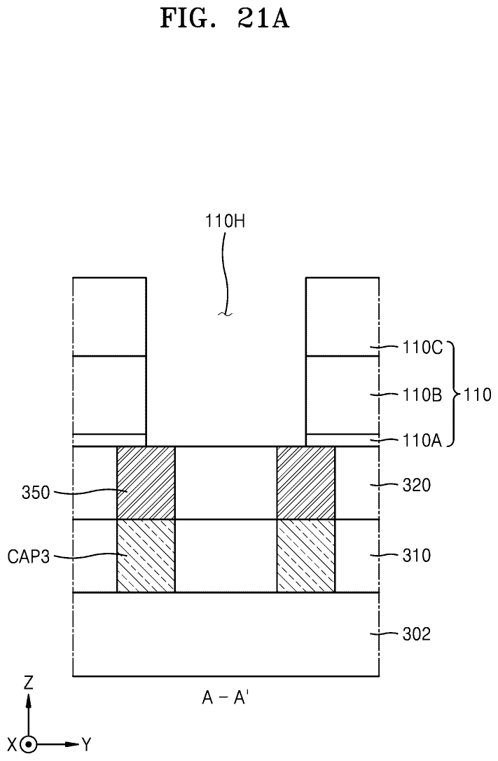

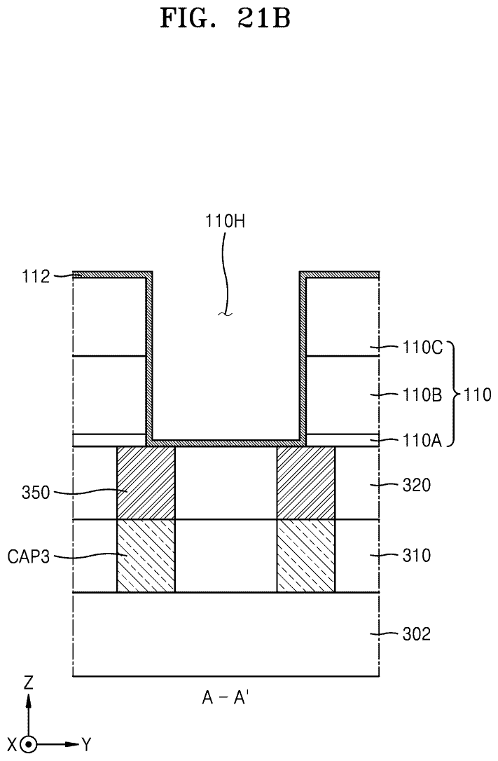

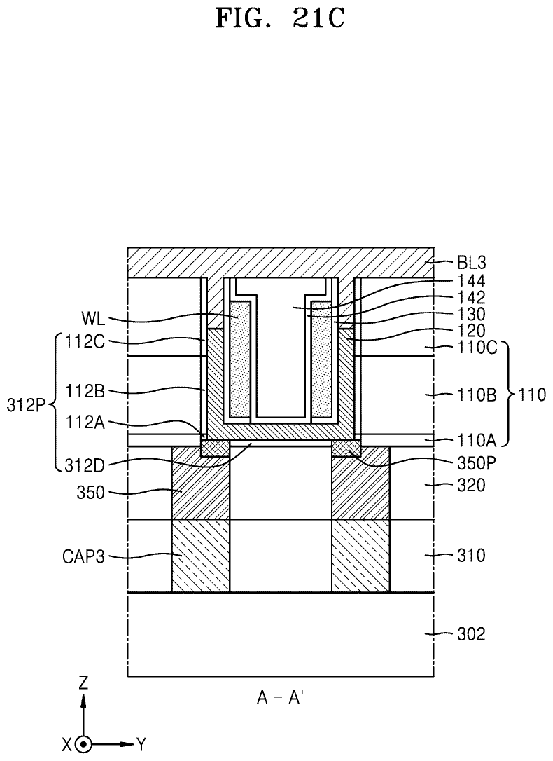

FIGS. 21A, 21B, and 21C are cross-sectional views of a process sequence of a method of manufacturing a semiconductor device, according to embodiments. FIGS. 21A, 21B, and 21C illustrate cross-sectional configurations of a portion corresponding to a cross-section taken along line A-A′ of FIG. 1, according to a process sequence. An example of a method of manufacturing the semiconductor device 300 shown in FIGS. 7 and 8 is described with reference to FIGS. 21A, 21B, and 21C. In FIGS. 21A, 21B, and 21C, the same reference numerals are used to denote the same elements as in FIGS. 1 to 8, and thus, repeated descriptions thereof are omitted.

Referring to FIG. 21A, a structure including a plurality of capacitor structures CAP3 and a first insulating layer 310 may be formed on a substrate 302, and then a structure including a plurality of conductive contact patterns 350 and a second insulating layer 320 may be formed. The plurality of conductive contact patterns 350 may be connected to the plurality of capacitor structure CAP3 on the plurality of capacitor structures CAP3.

Thereafter, by using a method similar to that described with reference to FIGS. 12A, 12B, 13A, and 13B, a mold insulating pattern 110 defining the plurality of openings 110H may be formed on the plurality of conductive contact patterns 350 and the second insulating layer 320.

Referring to FIG. 21B, by using a method similar to that described with reference to FIGS. 14A and 14B, a silicon-containing liner 112 may be formed on the resultant structure of FIG. 21A.

Referring to FIG. 21C, the processes described with reference to FIGS. 15A to 20 may be performed on the resultant structure of FIG. 21B. However, instead of forming a plurality of conductive contact patterns 150 to fill a plurality of contact spaces CTH, a process of forming a bit line BL3 in contact with a top surface of each of a pair of vertical channel portions VC included in the channel layer 120 may be performed.

To manufacture the semiconductor device 400 shown in FIG. 10, a method that combines the processes described with reference to FIGS. 21A, 21B, and 21C and the above-described processes for manufacturing the semiconductor device 200 shown in FIG. 6 may be used.

Although examples of the methods of manufacturing the semiconductor devices 100, 200, 300, and 400 shown in FIGS. 1 to 10 have been described with reference to FIGS. 12A to 21C, it will be understood that semiconductor devices having variously changed structures may be manufactured by applying various modifications and changes to the semiconductor devices 100, 200, 300, and 400 shown in FIGS. 1 to 10, based on the descriptions provided with reference to FIGS. 12A to 21C within the scope of the disclosed concepts.

According to aspects of the disclosed concepts, there is provided a method of manufacturing a semiconductor device. The method includes forming a conductive pattern on a substrate. A mold insulating pattern is formed to have an opening, which exposes a first region of the conductive pattern and extends in a first lateral direction. The mold insulating pattern covers a second region of the conductive pattern. A silicon-containing liner covering the first region of the conductive pattern is formed inside the opening of the mold insulating pattern. The resultant structure in which the silicon-containing liner is formed is annealed, and thus, a silicon-containing metal nitride film is formed from a portion of the silicon-containing liner, which is in contact with the first region of the conductive pattern, and the first region of the conductive pattern. A channel layer in contact with the silicon-containing metal nitride film is formed inside the opening of the mold insulating pattern.

In embodiments, during the formation of the silicon-containing liner, the silicon-containing liner is formed to conformally cover surfaces of the mold insulating pattern and inner surfaces of the opening of the mold insulating pattern.

In embodiments, the conductive pattern includes a bit line in a second lateral direction on the substrate. The second lateral direction is substantially perpendicular to the first lateral direction. During the formation of the silicon-containing liner, the silicon-containing liner is formed to contact a contact surface of the bit line. During the formation of the silicon-containing metal nitride film, the silicon-containing metal nitride film has a first width in the second lateral direction. During the formation of the channel layer, the channel layer has a second with less than the first width in the second lateral direction.

In embodiments, during the formation of the channel layer, the channel layer is formed to have a horizontal channel portion and a pair of vertical channel portions. The horizontal channel portion faces the contact surface of the bit line. The pair of vertical channel portions extend in a vertical direction from both ends of the horizontal channel portion in the second lateral direction. After the formation of the channel layer, the method further includes forming a pair of conductive contact patterns on the channel layer. Each of the pair of conductive contact patterns is formed to contact a selected one of the pair of vertical channel portions included in the channel layer.

In embodiments, the conductive pattern includes a plurality of conductive contact patterns arranged in a line in the second lateral direction on the substrate and spaced apart from one another in the second lateral direction. The second lateral direction is substantially perpendicular to the first lateral direction. During the formation of the silicon-containing liner, the silicon-containing liner is formed to contact a contact surface of each of a pair of adjacent ones of the plurality of conductive contact patterns. During the formation of the silicon-containing metal nitride film, the silicon-containing metal nitride film has a first width in the second lateral direction, During the formation of the channel layer, the channel layer has a second width greater than the first width in the second lateral direction.

In embodiments, the formation of the silicon-containing metal nitride film includes forming a first silicon-containing metal nitride film in contact with a contact surface of a first conductive contact pattern selected from the pair of conductive contact patterns and a second silicon-containing metal nitride film in contact with a contact surface of a second conductive contact pattern selected from the pair of conductive contact patterns. The first silicon-containing metal nitride film and the second silicon-containing metal nitride film are spaced apart from one another in the second lateral direction.

In embodiments, during the formation of the channel layer, the channel layer is formed to have a horizontal channel portion and a pair of vertical channel portions. The horizontal channel portion faces each of the pair of conductive contact patterns. The pair of vertical channel portions extend in the vertical direction from both ends of the horizontal channel portion in the second lateral direction. After the channel layer is formed, the method further includes forming a bit line on the channel layer. The bit line is formed to contact each of the pair of vertical channel portions included in the channel layer.

In embodiments, during the formation of the mold insulating pattern, the mold insulating pattern is formed to include a first mold insulating pattern and a second mold insulating pattern sequentially stacked on the conductive pattern in the vertical direction. The first mold insulating pattern and the second mold insulating pattern include different materials. The silicon-containing liner is formed to include portions in contact with the first mold insulating pattern and the second mold insulating pattern. During the formation of the silicon-containing metal nitride film, the method further includes forming an insulating liner structure including a first insulating liner portion in contact with the first mold insulating pattern of the mold insulating pattern and a second insulating liner portion in contact with the second mold insulating pattern of the mold insulating pattern from portions of the silicon-containing liner, which are in contact with the first mold insulating pattern and the second mold insulating pattern.

In embodiments, the first mold insulating pattern and the first insulating liner portion each include a silicon nitride film, a content ratio of nitrogen atoms in the silicon nitride film included in the first mold insulating pattern is higher than a content ratio of nitrogen atoms in the silicon nitride film included in the first insulating liner portion, the second mold insulating pattern and the second insulating liner portion each include a silicon oxide film, and a content ratio of oxygen atoms in the silicon oxide film included in the second mold insulating pattern is higher than a content ratio of oxygen atoms in the silicon oxide film included in the second insulating liner portion.

In embodiments, during the formation of the silicon-containing liner, the silicon-containing liner is formed by using a deposition process using a Si precursor selected from monosilane (SiH₄), dichlorosilane (DCS), tetraethoxysilane (TEOS), tetramethylsilane (TMS), hexachlorodisilane (HCD), disilane (Si₂H₆), hexamethyldisilane (HMDS), and trichlorosilane (TCS).

While the disclosed concepts have been particularly shown and described with reference to embodiments thereof, it will be understood that various changes in form and details may be made therein without departing from the spirit and scope of the following claims.

What is claimed is:

1. A semiconductor device comprising:
a metal-containing conductive line having a width in a first lateral direction and a length in a second lateral direction, wherein the second lateral direction is substantially perpendicular to the first lateral direction;
a metal-containing contact pattern spaced apart from the metal-containing conductive line in a vertical direction, the metal-containing contact pattern having a smaller length than the metal-containing conductive line in the second lateral direction;
a channel layer extending in the vertical direction between the metal-containing conductive line and the metal-containing contact pattern, the channel layer having an upper end in contact with a first conductive member and a lower end spaced apart from a second conductive member to face the second conductive member in the vertical direction, wherein the first conductive member is one of the metal-containing conductive line and the metal-containing contact pattern, and the second conductive member is the other one of the metal-containing conductive line and the metal-containing contact pattern; and
a silicon-containing metal nitride film between the second conductive member and the lower end of the channel layer, the silicon-containing metal nitride film having a first surface in contact with a contact surface of the second conductive member and a second surface in contact with the lower end of the channel layer.

2. The semiconductor device of claim 1, wherein the channel layer comprises an oxide semiconductor layer.

3. The semiconductor device of claim 1, wherein the second conductive member comprises a conductive metal nitride film.

4. The semiconductor device of claim 1, wherein:
the channel layer has a horizontal channel portion adjacent to the second conductive member and a pair of vertical channel portions, the horizontal channel portion extending in the second lateral direction, and the pair of vertical channel portions extending in the vertical direction from both ends of the horizontal channel portion in the second lateral direction, and the first conductive member is in contact with a selected one of the pair of vertical channel portions of the channel layer.

5. The semiconductor device of claim 1, wherein the silicon-containing metal nitride film has a thickness of about 10 Å to about 50 Å in the vertical direction.

6. The semiconductor device of claim 1, wherein:
the second conductive member comprises a titanium nitride (TiN) film,
the silicon-containing metal nitride film comprises a titanium silicon nitride (TiSiN) film, and
an atomic ratio of Si/(Ti+Si) in the TiSiN film is within a range of about 0.2 to about 1.0.

7. The semiconductor device of claim 1, further comprising:
a word line located on one side of the channel layer in the second lateral direction;
a gate dielectric film between the channel layer and the word line in the second lateral direction;
a mold insulating pattern located on another side of the channel layer in the second lateral direction, the mold insulating pattern being spaced apart from the gate dielectric film with the channel layer therebetween in the second lateral direction; and
an insulating liner structure between the mold insulating pattern and the channel layer in the second lateral direction, the insulating liner structure having a first surface in contact with the mold insulating pattern and a second surface in contact with the channel layer, wherein the mold insulating pattern comprises a first silicon oxide film and a first silicon nitride film, and
the insulating liner structure comprises a second silicon oxide film in contact with the first silicon oxide film and a second silicon nitride film in contact with the first silicon nitride film, a content ratio of oxygen atoms in the first silicon oxide film is higher than a content ratio of oxygen atoms in the second silicon oxide film, and a content ratio of nitrogen atoms in the first silicon nitride film is higher than a content ratio of nitrogen atoms in the second silicon nitride film.

8. The semiconductor device of claim 7, wherein the insulating liner structure overlaps the silicon-containing metal nitride film in the vertical direction.

9. The semiconductor device of claim 7, wherein:
the second conductive member comprises a non-contact surface in contact with the mold insulating pattern, and,
in the vertical direction, a first thickness from the contact surface of the second conductive member to a bottom surface of the second conductive member is less than a second thickness from the non-contact surface to the bottom surface of the second conductive member.

10. The semiconductor device of claim 1, further comprising:
a word line located on one side of the channel layer in the second lateral direction;
a gate dielectric film between the channel layer and the word line in the second lateral direction; and
a mold insulating pattern located on another side of the channel layer in the second lateral direction, the mold insulating pattern being spaced apart from the gate dielectric film in the second lateral direction with the channel layer therebetween,
wherein the mold insulating pattern has a surface in contact with the channel layer, and a partial region of the mold insulating pattern, which is adjacent to the channel layer, overlaps the silicon-containing metal nitride film in the vertical direction.

11. The semiconductor device of claim 10, wherein:
the second conductive member comprises a non-contact surface in contact with the mold insulating pattern, and,
in the vertical direction, a first thickness from the contact surface of the second conductive member to a bottom surface of the second conductive member is less than a second thickness from the non-contact surface to the bottom surface of the second conductive member.

12. The semiconductor device of claim 1, wherein, in the second lateral direction, a width of the silicon-containing metal nitride film is greater than a width of the channel layer and less than a width of the second conductive member.

13. The semiconductor device of claim 1, wherein, in the second lateral direction, a width of the silicon-containing metal nitride film is less than a width of the channel layer and less than a width of the second conductive member.

14. The semiconductor device of claim 1, further comprising a peripheral circuit structure spaced apart from the channel layer in the vertical direction with the second conductive member and the silicon-containing metal nitride film therebetween.

15. A semiconductor device comprising:
a mold insulating pattern on a substrate, the mold insulating pattern defining a transistor region extending lengthwise in a first lateral direction;
a channel layer located in the transistor region, the channel layer comprising a pair of vertical channel portions and a horizontal channel portion, the pair of vertical channel portions facing a sidewall of the mold insulating pattern in a second lateral direction and being spaced apart from one another in the second lateral direction, and the horizontal channel portion being located between the pair of vertical channel portions and integrally connected to one end of each of the pair of vertical channel portions, wherein the second lateral direction is substantially perpendicular to the first lateral direction;
a first conductive member in contact with at least one of the pair of vertical channel portions of the channel layer;
a second conductive member adjacent to the horizontal channel portion of the channel layer, the second conductive member being spaced apart from the first conductive member in the vertical direction with the channel layer therebetween; and
a silicon-containing metal nitride film between the second conductive member and the channel layer, the silicon-containing metal nitride film having a first surface in contact with a contact surface of the second conductive member and a second surface in contact with the horizontal channel portion of the channel layer.

16. The semiconductor device of claim 15, wherein:
the channel layer comprises an oxide semiconductor layer,
the second conductive member comprises a titanium nitride (TiN) film, and
the silicon-containing metal nitride film comprises a titanium silicon nitride (TiSiN) film.

17. The semiconductor device of claim 15, wherein:
the first conductive member comprises a first conductive contact pattern in contact with one of the pair of vertical channel portions of the channel layer and a second conductive contact pattern in contact with the other one of the pair of vertical channel portions, the second conductive contact pattern being spaced apart from the first conductive contact pattern in the second lateral direction,
the second conductive member comprises a bit line having a length greater than a length of the horizontal channel portion of the channel layer in the second lateral direction,
the first surface of the silicon-containing metal nitride film is in contact with a contact surface of the bit line, the second surface of the silicon-containing metal nitride film is in contact with the horizontal channel portion of the channel layer, and,
in the second lateral direction, a width of the silicon-containing metal nitride film is greater than a length of the horizontal channel portion of the channel layer and less than a width of the bit line.

18. The semiconductor device of claim 15, wherein:
the first conductive member comprises a bit line in contact with each of the pair of vertical channel portions of the channel layer,
the second conductive member comprises a first conductive contact pattern adjacent to a first portion of the horizontal channel portion of the channel layer and a second conductive contact pattern located adjacent to a second portion of the horizontal channel portion of the channel layer and spaced apart from the first conductive contact pattern in the second lateral direction, wherein the second portion is spaced apart from the first portion,
the silicon-containing metal nitride film comprises a first silicon-containing metal nitride film and a second silicon-containing metal nitride film spaced apart from one another in the second lateral direction, the first silicon-containing metal nitride film having a surface in contact with a contact surface of the first conductive contact pattern and a surface in contact with the first portion of the horizontal channel portion of the channel layer, and the second silicon-containing metal nitride film having a surface in contact with a contact surface of the second conductive contact pattern and a surface in contact with the second portion of the horizontal channel portion of the channel layer, and,
in the second lateral direction, a width of each of the first silicon-containing metal nitride film and the second silicon-containing metal nitride film is less than a width of each of the first conductive contact pattern and the second conductive contact pattern.

19. A semiconductor device comprising:
a bit line having a width in a first lateral direction and a length in a second lateral direction, wherein the second lateral direction is substantially perpendicular to the first lateral direction;
a pair of conductive contact patterns spaced apart from the bit line in a vertical direction and spaced apart from one another in the second lateral direction, each conductive contact pattern having a smaller length than the bit line in the second lateral direction;
a mold insulating pattern between the bit line and the pair of conductive contact patterns in the vertical direction, the mold insulating pattern defining a transistor region extending lengthwise in the first lateral direction;
a channel layer located in the transistor region, the channel layer comprising a pair of vertical channel portions and a horizontal channel portion, the pair of vertical channel portions facing a sidewall of the mold insulating pattern in the second lateral direction and being spaced apart from one another in the second lateral direction, and the horizontal channel portion being located between the pair of vertical channel portions and integrally connected to one end of each of the pair of vertical channel portions;
a pair of word lines located in the transistor region, the pair of word lines respectively facing and corresponding to the pair of vertical channel portions of the channel layer; and
a silicon-containing metal nitride film in contact with a bottom surface of the horizontal channel portion of the channel layer,
wherein one of the bit line and the pair of conductive contact patterns are in contact with the pair of vertical channel portions of the channel layer, and
the other one of the bit line and the pair of conductive contact patterns are adjacent to the horizontal channel portion of the channel layer, have contact surfaces in contact with the silicon-containing metal nitride film, and are spaced apart from the horizontal channel portion of the channel layer with the silicon-containing metal nitride film therebetween.

20. The semiconductor device of claim 19, wherein:
the channel layer comprises an oxide semiconductor layer,
each of the bit line and the pair of conductive contact patterns comprises a titanium nitride (TiN) film,
the silicon-containing metal nitride film comprises a titanium silicon nitride (TiSiN) film having a thickness of about 10 Å to about 50 Å in the vertical direction, and
an atomic ratio of Si/(Ti+Si) in the TiSiN film is within a range of about 0.2 to about 1.0.
